(19) United States
(12) Patent Application Publication
(10) Pub. No.: US 2026/0333802 A1
(43) Pub. Date: Oct. 22, 2026

(54) SEMICONDUCTOR DEVICE

(71) Applicant: Samsung Electronics Co., Ltd., Suwon-si (KR)

(72) Inventors: Youngrok KIM, Suwon-si (KR); Sangjae LEE, Suwon-si (KR); Kangoh YUN, Suwon-si (KR); Yero LEE, Suwon-si (KR); Jaewoong CHOI, Suwon-si (KR)

(73) Assignee: Samsung Electronics Co., Ltd., Suwon-si (KR)

(21) Appl. No.: 19/649,323

(22) Filed: Apr. 16, 2026

(30) Foreign Application Priority Data
Apr. 21, 2025 (KR) 10-2025-0051828

(51) Int. Cl. H10D 62/17; H10D 30/01; H10D 30/62; H10D 64/23; H10D 64/27

(52) U.S. Cl. CPC H10D 62/292; H10D 30/6211; H10D 30/6219; H10D 64/257; H10D 64/514; H10D 64/518; H10D 30/024

(57) ABSTRACT

A semiconductor device includes a substrate, a fin-type body protruding vertically on the substrate and extending in a first horizontal direction, a first source/drain region on a first side of the fin-type body and a second source/drain region on a second side of the fin-type body, a channel region between the first and second source/drain regions in the fin-type body, a gate electrode surrounding the channel region and extending in a second horizontal direction that is perpendicular to and intersects with the first horizontal direction, a gate dielectric film between the channel region and the gate electrode, and a first contact on the first source/drain region and a second contact on the second source/drain region. The channel region extends in a first oblique direction, and an imaginary straight line connecting furthest ends of the first and second contacts extends in a second oblique direction transverse to the first oblique direction.

### CROSS-REFERENCE TO RELATED APPLICATIONS

This application claims priority under 35 U.S.C. §119 to Korean Patent Application No. 10-2025-0051828, filed on Apr. 21, 2025, in the Korean Intellectual Property Office, the disclosure of which is incorporated by reference herein in its entirety.

### BACKGROUND

Some example embodiments of the inventive concepts relate to a semiconductor device including a high-voltage transistor.

Semiconductor devices have a high integration density due to the advances in semiconductor processes, and it is advantageous for the semiconductor devices to have improved performance. For example, small-sized semiconductor devices may reduce the area of an integrated circuit, and large-sized semiconductor devices may provide improved operating speed of the integrated circuit. High-voltage transistors may be used in single-chip system technology for a variety of applications such as input/output interface circuits, power management circuits, and driver circuits for radio-frequency (RF) amplifiers.

### SUMMARY

Some example embodiments of the inventive concepts provide a semiconductor device including a high-voltage transistor having improved electrical characteristics and integration density.

Example embodiments of the inventive concept are not limited to the example embodiments described herein, and other embodiments not mentioned herein will be clearly understood by those skilled in the art from the description below.

According to some example embodiments of the inventive concepts, a semiconductor device includes a substrate, a fin-type body protruding vertically on the substrate and extending in a first horizontal direction, a first source/drain region on a first side of the fin-type body and a second source/drain region on a second side of the fin-type body, a channel region between the first source/drain region and the second source/drain region in the fin-type body, a gate electrode surrounding the channel region and extending in a second horizontal direction that is perpendicular to and intersects the first horizontal direction, a gate dielectric film between the channel region and the gate electrode, and a first contact on the first source/drain region and a second contact on the second source/drain region. The channel region extends in a first oblique direction, and an imaginary straight line connecting furthest ends of the first contact and the second contact extends in a second oblique direction transverse to the first oblique direction.

According to some example embodiments of the inventive concepts, a semiconductor device includes a transistor on a substrate. The transistor includes a fin-type body extending in a first horizontal direction, a first source/drain region defining a first side of the fin-type body and a second source/drain region defining a second side of the fin-type body, a channel region defining a portion between the first source/drain region and the second source/drain region of the fin-type body, a gate electrode surrounding the channel region and extending in a second horizontal direction that is perpendicular to and intersects the first horizontal direction, a gate dielectric film between the channel region and the gate electrode, and a first contact on the first source/drain region and a second contact on the second source/drain region. The channel region extends in a zigzag manner in the first horizontal direction and the second horizontal direction, a first imaginary straight line connecting furthest ends of the channel region extends in a first oblique direction, and a second imaginary straight line connecting furthest ends of the first contact and the second contact extends in a second oblique direction transverse to the first oblique direction.

According to some example embodiments of the inventive concepts, a semiconductor device includes a high-voltage transistor. The high-voltage transistor includes a substrate, a fin-type body, the fin-type body defining a portion of the substrate, and protruding in a vertical direction on an upper surface of the substrate and extending in a first horizontal direction, a gate electrode surrounding a central portion of the fin-type body on the substrate and extending in a second horizontal direction that is perpendicular to and intersects the first horizontal direction, a gate dielectric film between the fin-type body and the gate electrode, a source region having a rectangular shape and defining a first side of the fin-type body and a drain region having a rectangular shape and defining a second side of the fin-type body, a channel region defining a central portion of the fin-type body and extending in a first diagonal direction between a sidewall of the source region and a sidewall of the drain region, the sidewall of the source region and the sidewall of the drain region facing each other, and a source contact on the source region and a drain contact on the drain region. A first imaginary straight line connecting furthest ends of the source contact and the drain contact extends in a second diagonal direction transverse to the first diagonal direction.

### BRIEF DESCRIPTION OF THE FIGURES

Example embodiments will be more clearly understood from the following detailed description taken in conjunction with the accompanying drawings in which:

FIG. 1 is a perspective view illustrating a semiconductor device according to some example embodiments.

FIG. 2 is a plan view illustrating the semiconductor device of FIG. 1.

FIG. 3 is a cross-sectional view taken along line B-B′ of FIG. 2.

FIG. 4 is a cross-sectional view taken along line C-C′ of FIG. 2.

FIG. 5 is a cross-sectional view taken along line D-D′ of FIG. 2.

FIGS. 6, 7, 8, and 9 are perspective views and plan views illustrating semiconductor devices according to some example embodiments.

FIGS. 10A to 25D are plan views and cross-sectional views illustrating processes in a method of manufacturing a semiconductor device, according to some example embodiments. FIGS. 10A, 11A, 12A, 13A, 14A, 15A, 16A, 17A, 18A, 19A, 20A, 21A, 22A, 23A, 24A, and 25A are plan views showing the processes in the method of manufacturing the semiconductor device. FIGS. 10B, 11B, 12B, 13B, 14B, 15B, 16B, 17B, 18B, 19B, 20B, 21B, 22B, 23B, 24B, and 25B are cross-sectional views taken along line B-B′ of FIGS. 10A, 11A, 12A, 13A, 14A, 15A, 16A, 17A, 18A, 19A, 20A, 21A, 22A, 23A, 24A, and 25A, respectively. FIGS. 10C, 11C, 12C, 13C, 14C, 15C, 16C, 17C, 18C, 19C, 20C, 21C, 22C, 23C, 24C, and 25C are cross-sectional views taken along line C-C′ of FIGS. 10A, 11A, 12A, 13A, 14A, 15A, 16A, 17A, 18A, 19A, 20A, 21A, 22A, 23A, 24A, and 25A, respectively. FIGS. 10D, 11D, 12D, 13D, 14D, 15D, 16D, 17D, 18D, 19D, 20D, 21D, 22D, 23D, 24D, and 25D are cross-sectional views taken along line D-D′ of FIGS. 10A, 11A, 12A, 13A, 14A, 15A, 16A, 17A, 18A, 19A, 20A, 21A, 22A, 23A, 24A, and 25A, respectively.

### DETAILED DESCRIPTION OF EXAMPLE EMBODIMENTS

Hereinafter, example embodiments will be described in detail with reference to the attached drawings.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

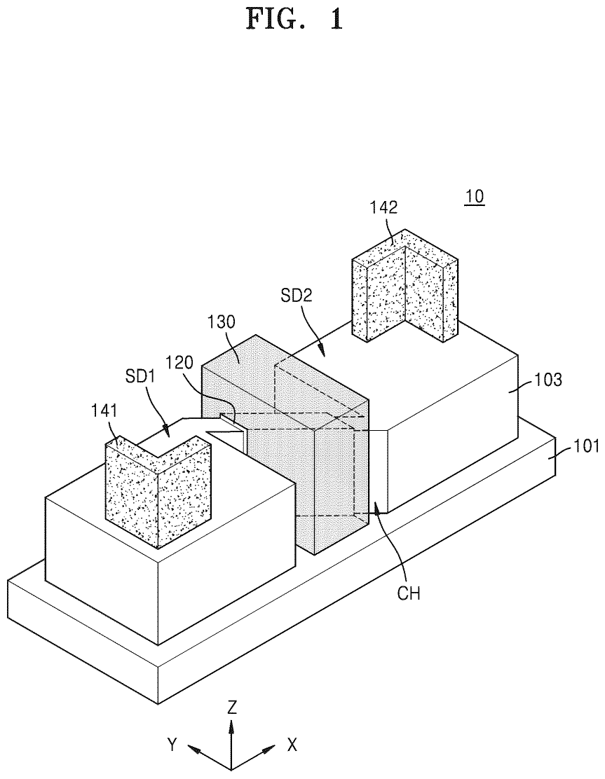

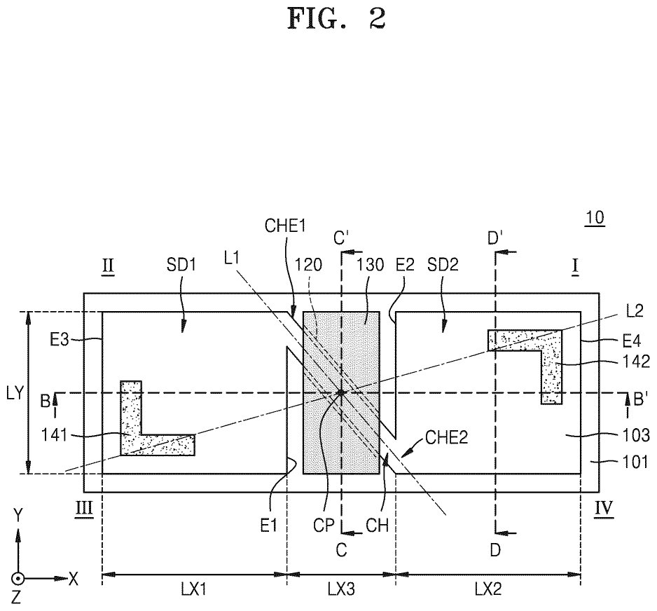

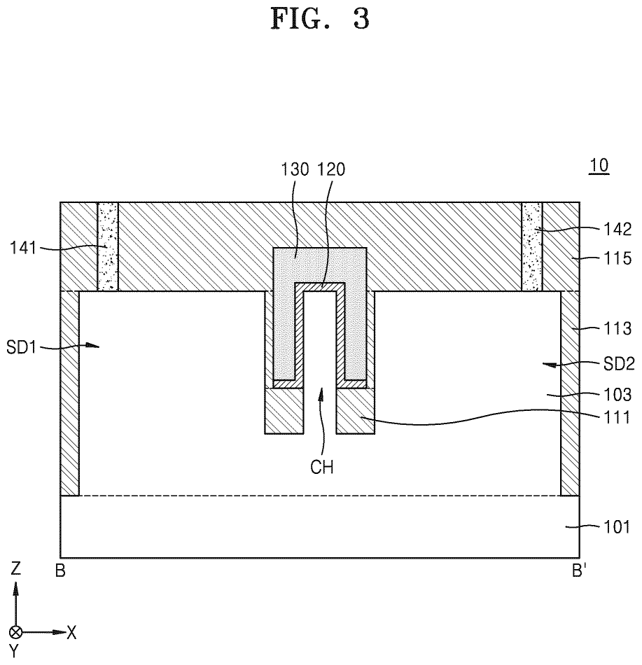

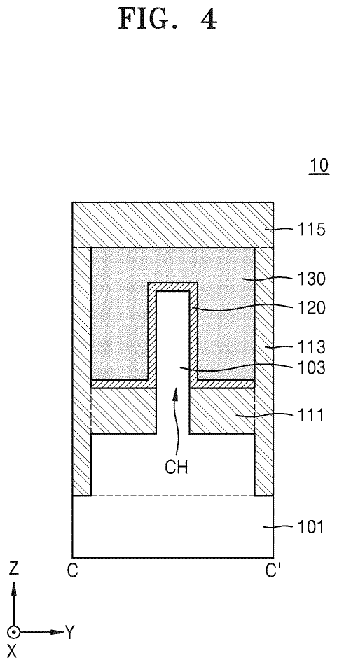

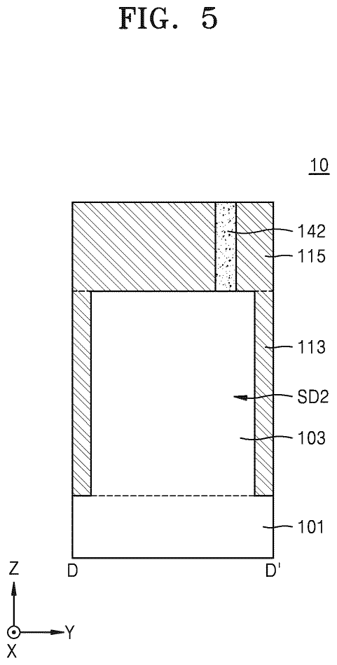

FIG. 1 is a perspective view illustrating a semiconductor device according to some example embodiments. FIG. 2 is a plan view illustrating the semiconductor device of FIG. 1. FIG. 3 is a cross-sectional view taken along line B-B′ of FIG. 2. FIG. 4 is a cross-sectional view taken along line C-C′ of FIG. 2. FIG. 5 is a cross-sectional view taken along line D-D′ of FIG. 2.

For convenience of description and understanding, a lower insulating layer 111, a sidewall insulating layer 113, and an upper insulating layer 115 are omitted in FIGS. 1 and 2.

Referring to FIGS. 1 to 5, a semiconductor device 10, according to some example embodiments, may include a high-voltage transistor. For the purposes of discussion herein, a high-voltage transistor may refer to a transistor having an operating voltage of 20 V or higher.

In the semiconductor device 10, a conductivity type or a doping region of components may be defined as p-type or n-type, depending on the characteristics of a main carrier, but this is for convenience of description, and example embodiments are not limited to the examples. For example, p-type or n-type may be referred to as first-conductivity type or second-conductivity type, which is the opposite of first-conductivity type.

A substrate 101 may be a semiconductor wafer including silicon (Si). In some example embodiments, the substrate 101 may be a wafer including a semiconductor device such as germanium (Ge), or a compound semiconductor such as silicon carbide (SiC), gallium arsenide (GaAs), indium arsenide (InAs), or indium phosphide (InP). The substrate 101 may have a silicon on insulator (SOI) structure.

The substrate 101 may include a peripheral circuit area in which transistors constituting a peripheral circuit of the semiconductor device 10 are arranged. For example, logic transistors that constitute a row decoder, a read/write circuit, control logic, and a voltage generator that generates different voltages for operation may be formed on the substrate 101. Additionally, the substrate 101 may include a memory cell region in which a plurality of memory cells for storing data of the semiconductor device 10 are formed. For example, vertical memory devices having a three-dimensional structure may be formed on the substrate 101.

The substrate 101 may include an n-type metal oxide semiconductor field-effect transistor (nMOSFET) region and a p-type metal oxide semiconductor field-effect transistor (pMOSFET) region of the semiconductor device 10. Here, the nMOSFET region may be defined as a region in which at least one n-type transistor is arranged, and the pMOSFET region may be defined as a region in which at least one p-type transistor is arranged.

A fin-type body 103 may be formed on the substrate 101. The fin-type body 103 may protrude or extend in a vertical direction (Z direction) on the substrate 101 and may extend in a first horizontal direction (X direction). The fin-type body 103 may be formed by patterning the substrate 101 by using a photolithography process. Accordingly, the fin-type body 103 may include substantially the same material and substantially the same crystal structure as the substrate 101.

The lower insulating layer 111 and the sidewall insulating layer 113 may be formed on opposite sides of the fin-type body 103 to prevent or limit electrical connection between the fin-type body 103 and other elements. Here, an upper surface of the lower insulating layer 111 may be formed to have a lower vertical level than the upper surface of the fin-type body 103. The lower surface of the sidewall insulating layer 113 may extend to the upper surface of the substrate 101. The lower surface of the lower insulating layer 111 may be spaced from the upper surface of the substrate 101. For example, the fin-type body 103 may have a fin shape protruding from the lower insulating layer 111 in the vertical direction (Z direction). The lower insulating layer 111 and the sidewall insulating layer 113 may each include at least one of, for example, silicon oxide, silicon nitride, silicon oxynitride, or a low-k dielectric film.

Inside the fin-type body 103, a first source/drain region SD1, a channel region CH, and a second source/drain region SD2 may be formed sequentially in the first horizontal direction (X direction). The first source/drain region SD1 and the second source/drain region SD2 may be formed on opposite sides of the fin-type body 103. For example, the first source/drain region SD1 may be referred to as a source region, and the second source/drain region SD2 may be referred to as a drain region.

In some example embodiments, the first source/drain region SD1 and the second source/drain region SD2 may be formed by forming a photomask on the fin-type body 103 and using the formed photomask to implant a high concentration dopant, for example, an n-type dopant, into the fin-type body 103 in which the first source/drain region SD1 and the second source/drain region SD2 are formed.

The channel region CH may be formed between the first source/drain region SD1 and the second source/drain region SD2 within the fin-type body 103. In some example embodiments, the channel region CH may be formed in a first oblique direction (L1 direction) in a space between the first source/drain region SD1 and the second source/drain region SD2. Here, the first oblique direction (L1 direction) may be referred to as a first diagonal direction. In some example embodiments, the first source/drain region SD1, the second source/drain region SD2, and the channel region CH have a same height in the vertical direction (Z direction) with reference to an upper or top surface of the substrate 101. In some example embodiments, the first source/drain region SD1, the second source/drain region SD2, and the channel region CH have a same material and a same crystal structure.

A gate dielectric film 120 may be formed on the channel region CH. The gate dielectric film 120 may be formed to surround both an upper surface and both side surfaces of the channel region CH. In some example embodiments, the gate dielectric film 120 may include silicon oxide or silicon oxynitride. In some example embodiments, the gate dielectric film 120 may include at least one of high-k dielectric films. For example, the gate dielectric film 120 may include, but is not limited to, at least one of hafnium oxide, hafnium silicate, zirconium oxide, and zirconium silicate.

A gate electrode 130 may be formed on the gate dielectric film 120 on the channel region CH. The gate electrode 130 may extend in a second horizontal direction (Y direction) that perpendicularly intersects with the first horizontal direction (X direction). Although the drawing illustrates that one gate electrode 130 is formed on the channel region CH of one fin-type body 103, example embodiments of the inventive concepts are not limited thereto. For example, one gate electrode 130 may be formed across the channel region CH of a plurality of fin-type bodies 103 spaced apart from each other in the second horizontal direction (Y direction).

The gate electrode 130 may include a conductive material. The gate electrode 130 may include doped polysilicon, a metal, or a combination thereof. For example, the gate electrode 130 may include, but is not limited to, Al, Cu, Ti, Ta, W, Mo, TaN, NiSi, CoSi, TiN, WN, TiAl, TiAlN, TaCN, TaC, TaSiN, TiAlC, or a combination thereof.

In some example embodiments, the gate electrode 130 may include a work function metal-including layer and a gapfill metal film. The work function metal-including layer may include at least one metal selected from Ti, W, Ru, Nb, Mo, Hf, Ni, Co, Pt, Yb, Tb, Dy, Er, and Pd. The gapfill metal film may include tungsten (W) or aluminum (Al).

In some example embodiments, the gate electrode 130 may have a stacked structure, such as a stacked structure of TiAlC/TiN/W, a stacked structure of TiN/TaN/TiAlC/TiN/W, or a stacked structure of TiN/TaN/TiN/TiAlC/TiN/W.

A first contact 141 may be formed on the first source/drain region SD1, and a second contact 142 may be formed on the second source/drain region SD2. The first and second contacts 141 and 142 may include a conductive material. The first and second contacts 141 and 142 may include, but are not limited to, Al, Cu, Ti, Ta, W, Mo, TaN, NiSi, CoSi, TiN, WN, TiAl, TiAlN, TaCN, TaC, TaSiN, TiAlC, or a combination thereof, for example. Here, the first contact 141 may be referred to as a source contact, and the second contact 142 may be referred to as a drain contact.

The upper insulating layer 115 may be formed to surround the first and second contacts 141 and 142 on the fin-type body 103. The upper insulating layer 115 may include an insulating material similar to the lower insulating layer 111 and the sidewall insulating layer 113, and may include, for example, at least one of silicon oxide, silicon nitride, silicon oxynitride, or a low-k film.

In the semiconductor device 10, the channel region CH may extend in the first oblique direction (L1 direction) in the space between the first source/drain region SD1 and the second source/drain region SD2. Additionally, the first and second contacts 141 and 142 may be formed at positions where an imaginary straight line connecting the furthest ends of the first and second contacts 141 and 142 extends in a second oblique direction (L2 direction) transverse to the first oblique direction (L1 direction). For example, the furthest ends of the first and second contacts 141 and 142 may refer to ends of the first and second contacts 141 and 142 furthest from each other. Here, the second oblique direction (L2 direction) may be referred to as a second diagonal direction.

For example, assuming a four-quadrant configuration formed by the first horizontal direction (X direction) and the second horizontal direction (Y direction), the first oblique direction (L1 direction) may be positioned to pass through the second quadrant (II) and the fourth quadrant (IV) of the four quadrants, and the second oblique direction (L2 direction) may be positioned to pass through the first quadrant (I) and the third quadrant (III) of the four quadrants.

In some example embodiments, in a plan view, the first and second source/drain regions SD1 and SD2 may each have a rectangular shape, and the channel region CH may be formed in a parallelogram shape, thereby forming the fin-type body 103. For example, the first and second source/drain regions SD1 and SD2 may have an expanded or increased or greater area compared to the channel region CH.

In some example embodiments, with respect to the first horizontal direction (X direction), a length LX1 of the first source/drain region SD1 and a length LX2 of the second source/drain region SD2 may be substantially equal to each other, and a length LX3 of the channel region CH may be less than each of the lengths LX1, LX2 of the first and second source/drain regions SD1 and SD2. Additionally, with respect to the second horizontal direction (Y direction), the length of the first source/drain region SD1, the length of the second source/drain region SD2, and the length of the channel region CH may be substantially equal to each other, and are collectively indicated as length LY in FIG. 2.

One end CHE1 of the channel region CH may contact a first edge E1 of the first source/drain region SD1, and the other end CHE2 of the channel region CH may contact a second edge E2 of the second source/drain region SD2. Accordingly, the fin-type body 103 may have a zee (Z) shape in general.

Additionally, the first contact 141 may be formed adjacent an edge E3 of the first source/drain region SD1, which is furthest from the first edge E1, and the second contact 142 may be formed adjacent an edge E4 of the second source/drain region SD2, which is furthest from the second edge E2.

In some example embodiments, in a plan view illustrated in FIG. 2, the first and second contacts 141 and 142 may have a point-symmetrical structure with respect to a center point CP that is located on the imaginary straight line in the first oblique direction (L1 direction). Stated otherwise, the first and second contacts 141 and 142 may have a point-symmetrical structure with respect to a center point CP and about the imaginary straight line in the first oblique direction (L1 direction). The center point CP may be or otherwise define the intersection point of the imaginary straight line in the first oblique direction (L1 direction) and the imaginary straight line in the second oblique direction (L2 direction). As illustrated in FIG. 2, in a plan view, the channel region CH is point-symmetrical with respect to the center point CP and about the imaginary straight line in the second oblique direction (L2 direction). In some example embodiments, the center point CP may be the center of the channel region CH. For example, the first contact 141 may have an L-shape including a portion extending in the first horizontal direction (X direction) and a portion extending in the second horizontal direction (Y direction), and the second contact 142 may have a reversed or inverted L-shape with respect to the first contact 141, which includes a portion extending in the first horizontal direction (X direction) and a portion extending in the second horizontal direction (Y direction). Accordingly, a reduced gap between the first and second contacts 141 and 142 and the channel region CH of a desired channel length may be obtained and a desired contact area between the first and second contacts 141 and 142 and the first and second source/drain regions SD1 and SD2 may be obtained.

The semiconductor device 10 may have a relatively higher integration due improvements in the development of semiconductor processes, and it may also be beneficial for the semiconductor device 10 to have a relatively higher performance. For example, the semiconductor device 10 of a compact size may reduce the area of an integrated circuit, and the semiconductor device 10 of a larger size may be advantageous in improving the electrical characteristics of an integrated circuit.

A high-voltage transistor may be used in single-chip system technology for a variety of applications such as input/output interface circuits, power management circuits, and driver circuits for radio-frequency (RF) amplifiers. For the purposes of discussion herein, a high-voltage transistor may refer to a transistor having an operating voltage of 20 V or higher.

Improvements in the integration and electrical characteristics of transistors arranged in a peripheral circuit area are beneficial to control a relatively larger number of memory cells at high speed. As fin-type field effect transistor (FinFET) including the fin-type body 103 is also used in the peripheral circuit area, a structure that connects the FinFET to a high-voltage transistor is also desired.

A FinFET structure of a high-voltage transistor that enables electric field dispersion without breakdown at high operating voltage and provides sufficient current even at a relatively higher body bias is desirable. Along with the improvement of electrical characteristics of these high-voltage transistors, reduction in the area of the peripheral circuit area is also desirable.

A FinFET structure that may simultaneously satisfy the requirements of increasing the area of the first and second source/drain regions SD1 and SD2 and reducing the overall transistor area in a high-voltage transistor is desirable.

In the semiconductor device 10, according to example embodiments of the inventive concepts, the channel region CH is formed in the first oblique direction (L1 direction) in the fin-type body 103. Accordingly, a distance between the first and second source/drain regions SD1 and SD2 may be reduced while maintaining an effective channel length of the channel region CH. The channel length of the channel region CH may provide or generate the desired amount of channel current for a more improved operation of the semiconductor device 10. Accordingly, the first and second source/drain regions SD1 and SD2 may be expanded (or otherwise increased in size) and formed by the area in which distance between the first and second source/drain regions SD1 and SD2 is relatively reduced. In addition, in order to prevent or limit the electric field dispersion effect from being reduced due to the distance between the first and second source/drain regions SD1 and SD2 being reduced and the first and second contacts 141 and 142 and the channel region CH coming relatively closer, the first and second contacts 141 and 142 may be formed at positions extending in the second oblique direction (L2 direction) transverse to the first oblique direction (L1 direction). As a result, the effect of electric field dispersion may be maintained while obtaining a reduced gap between the first and second contacts 141 and 142 and an increased length of the channel region CH.

The semiconductor device 10 may thus have improved electrical characteristics due to the increased size of the first and second source/drain regions SD1 and SD2, and also the semiconductor device 10 may improve or increase device integration by forming the channel region CH in the first oblique direction (L1 direction) and forming the first and second contacts 141, 142 in the second oblique direction (L2 direction).

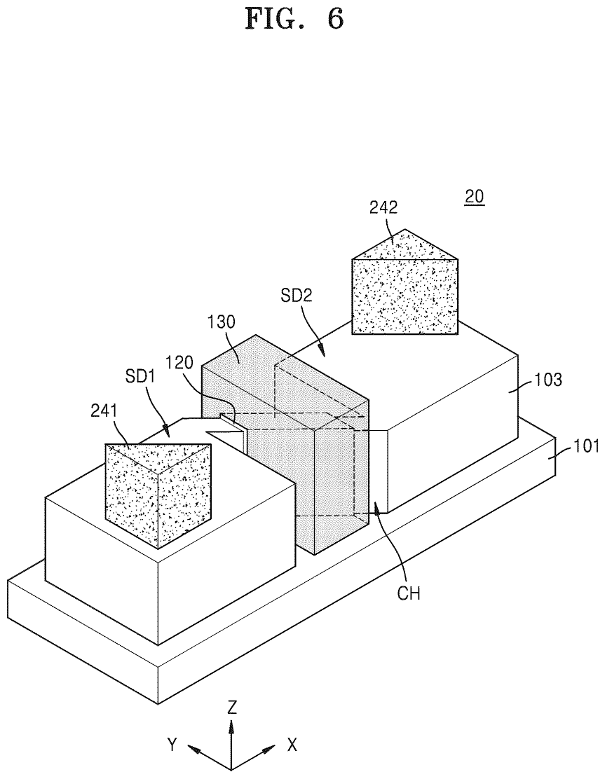

FIGS. 6, 7, 8, and 9 are perspective views and plan views illustrating semiconductor devices 20 and 30, according to some example embodiments.

The semiconductor devices 20 and 30 may be same as or similar in some respects to the semiconductor device 10 of FIGS. 1-5, and therefore may be best understood with reference thereto where like numerals indicate like elements not described again in detail.

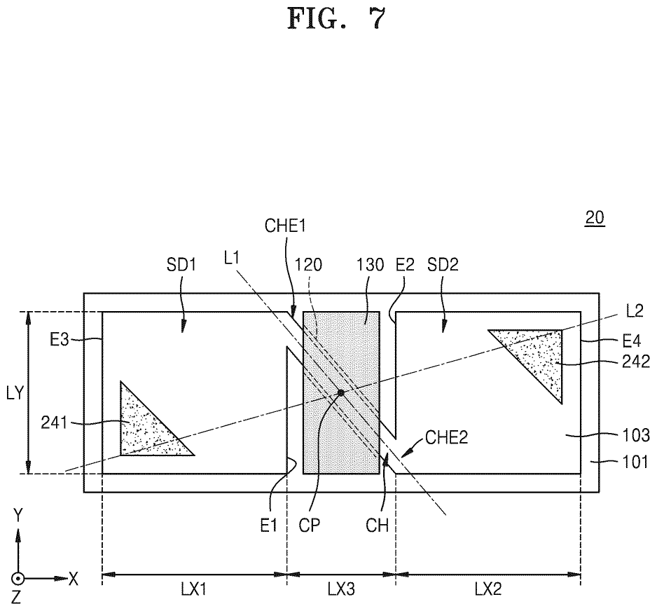

Referring to FIGS. 6 and 7, the semiconductor device 20 may include a high-voltage transistor.

In the semiconductor device 20, a first contact 241 may be formed on the first source/drain region SD1, and a second contact 242 may be formed on the second source/drain region SD2. The first and second contacts 241 and 242 may include a conductive material. The first and second contacts 241 and 242 may include, but are not limited to, Al, Cu, Ti, Ta, W, Mo, TaN, NiSi, CoSi, TiN, WN, TiAl, TiAlN, TaCN, TaC, TaSiN, TiAlC, or a combination thereof, for example. Here, the first contact 241 may be referred to as a source contact, and the second contact 242 may be referred to as a drain contact.

In the semiconductor device 20, the channel region CH may extend in the first oblique direction (L1 direction) in the space between the first source/drain region SD1 and the second source/drain region SD2. Additionally, the first and second contacts 241 and 242 may be formed at positions where an imaginary straight line connecting the furthest ends of the first and second contacts 241, 242 extends in the second oblique direction (L2 direction) transverse to the first oblique direction (L1 direction).

In the semiconductor device 20, the first and second contacts 241 and 242 may have a point-symmetrical structure based on the center point CP located on the imaginary straight line in the first oblique direction (L1 direction). Stated otherwise, the first and second contacts 241 and 242 may have a point-symmetrical structure with respect to the center point CP and about the imaginary straight line in the first oblique direction (L1 direction). For example, the first contact 241 may have a triangular shape, and the second contact 242 may have an inverted triangular shape with respect to the first contact 241. Accordingly, a reduced gap between the first and second contacts 241 and 242 and the channel region CH of a desired channel length may be obtained, and a desired contact area between the first and second contacts 241 and 242 and the first and second source/drain regions SD1 and SD2 may be obtained.

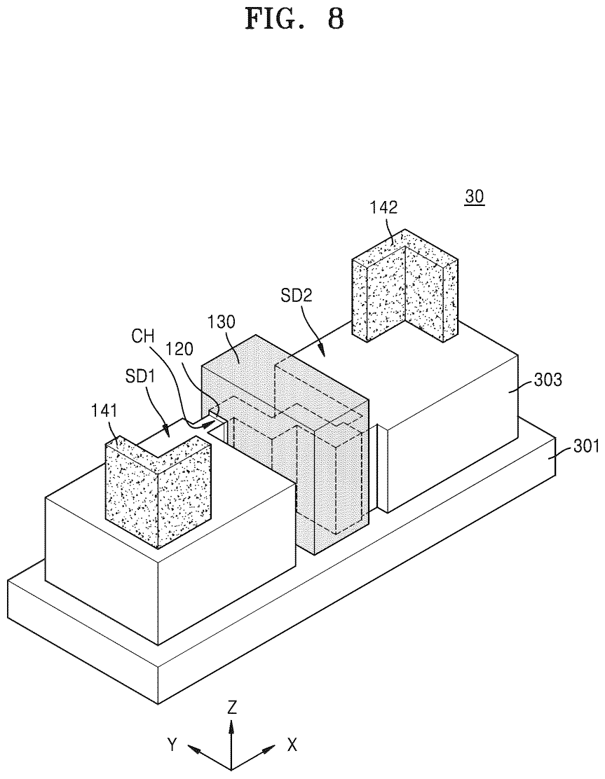

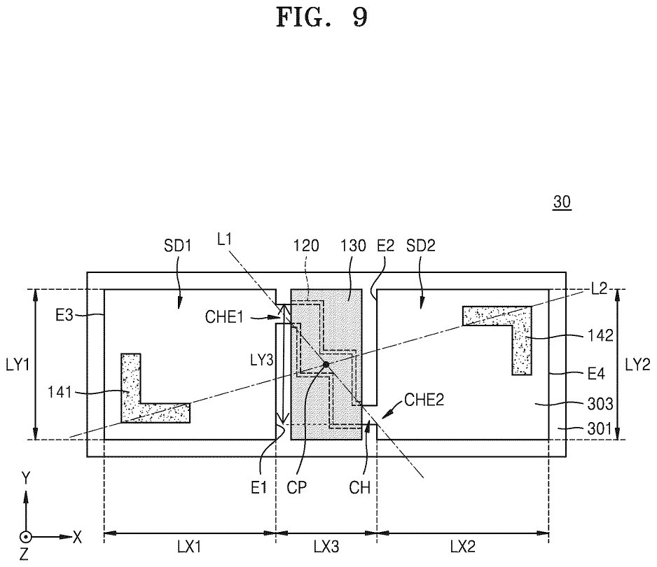

Referring to FIGS. 8 and 9, the semiconductor device 30 may include a high-voltage transistor.

In the semiconductor device 30, a substrate 301 may be a semiconductor wafer including silicon (Si). A fin-type body 303 may be formed on the substrate 301. The fin-type body 303 may be formed to protrude or extend in the vertical direction (Z direction) on the substrate 301 and may be formed to extend in the first horizontal direction (X direction). The fin-type body 303 may include substantially the same material and substantially the same crystal structure as the substrate 301.

In the semiconductor device 30, the channel region CH may be formed between the first source/drain region SD1 and the second source/drain region SD2 within the fin-type body 303. The channel region CH may extend in a zigzag manner in the first horizontal direction (X direction) and the second horizontal direction (Y direction) in the space between the first source/drain region SD1 and the second source/drain region SD2. For example, of the channel region CH, the number of portions extending in the first horizontal direction (X direction) (three portions illustrated in FIG. 9) may be one more than the number of portions extending in the second horizontal direction (Y direction) (two portions illustrated in FIG. 9).

In the semiconductor device 30, an imaginary straight line connecting the furthest ends of the channel region CH may extend in the first oblique direction (L1 direction). Additionally, the first and second contacts 141 and 142 may be formed at positions where the imaginary straight line connecting the furthest ends of the first and second contacts 141 and 142 extends in the second oblique direction (L2 direction) transverse to the first oblique direction (L1 direction).

In the semiconductor device 30, in a plan view in FIG. 9, the first and second source/drain regions SD1 and SD2 may each have a rectangular shape, and the channel region CH may be in a zigzag shape, thereby forming the fin-type body 303. As a result, the first and second source/drain regions SD1 and SD2 may have an expanded or increased area compared to the channel region CH.

In the semiconductor device 30, with respect to the first horizontal direction (X direction), the length LX1 of the first source/drain region SD1 may be substantially equal to the length LX2 of the second source/drain region SD2, and the length LX3 of the channel region CH may be less than each of the lengths LX1 and LX2 of the first and second source/drain regions SD1 and SD2. Additionally, with respect to the second horizontal direction (Y direction), a length LY1 of the first source/drain region SD1 may be substantially equal to a length LY2 of the second source/drain region SD2, and a length LY3 of the channel region CH may be less than each of the lengths LY1 and LY2 of the first and second source/drain regions SD1 and SD2.

In the semiconductor device 30, instead of the L-shape as shown, the first contact 141 may have a triangular shape, and the second contact 142 may have an inverted triangular shape with respect to the first contact 141, similar to the shapes of the first contact 141 and the second contact 142 in FIGS. 6 and 7.

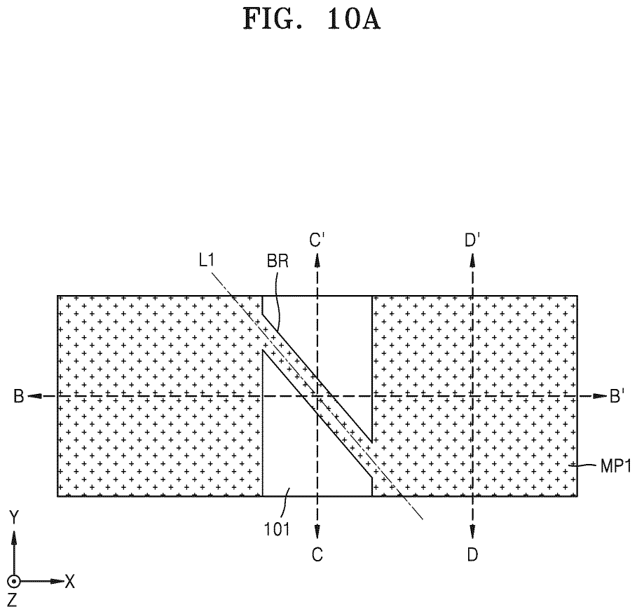

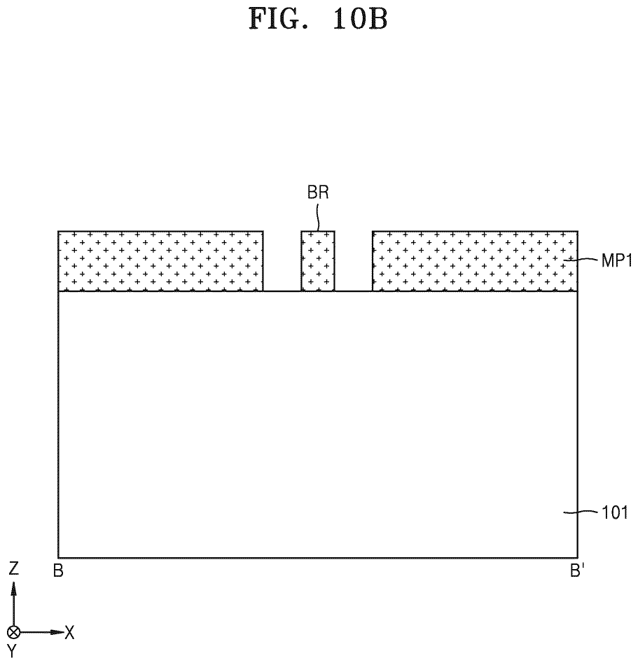

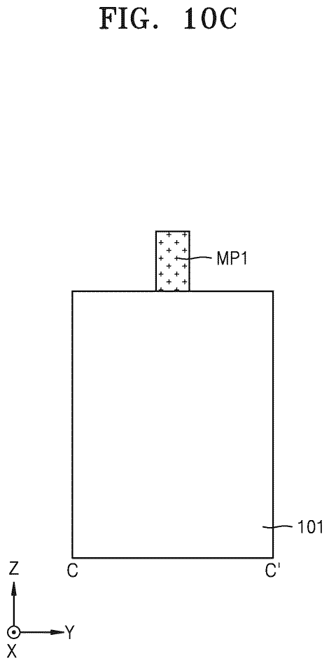

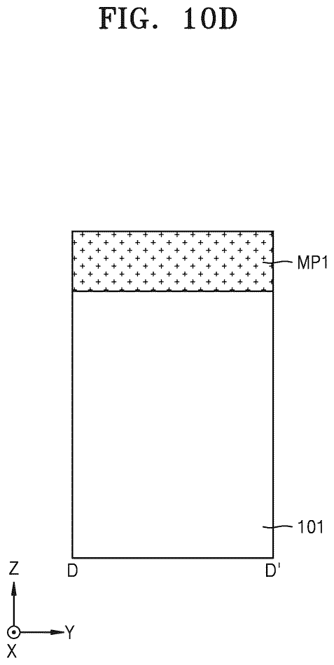

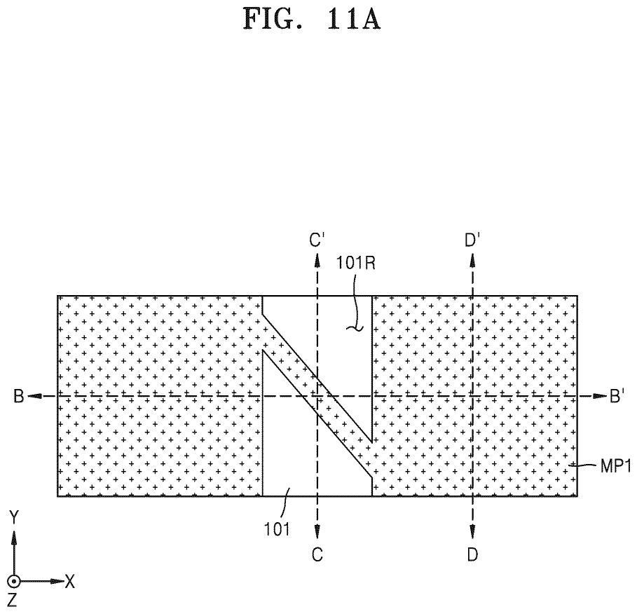

FIGS. 10A to 25D are plan views and cross-sectional views illustrating processes in a method of manufacturing a semiconductor device, according to some example embodiments.

FIGS. 10A, 11A, 12A, 13A, 14A, 15A, 16A, 17A, 18A, 19A, 20A, 21A, 22A, 23A, 24A, and 25A are plan views showing the processes in the method of manufacturing the semiconductor device. FIGS. 10B, 11B, 12B, 13B, 14B, 15B, 16B, 17B, 18B, 19B, 20B, 21B, 22B, 23B, 24B, and 25B are cross-sectional views taken along line B-B′ of FIGS. 10A, 11A, 12A, 13A, 14A, 15A, 16A, 17A, 18A, 19A, 20A, 21A, 22A, 23A, 24A, and 25A, respectively. FIGS. 10C, 11C, 12C, 13C, 14C, 15C, 16C, 17C, 18C, 19C, 20C, 21C, 22C, 23C, 24C, and 25C are cross-sectional views taken along line C-C′ of FIGS. 10A, 11A, 12A, 13A, 14A, 15A, 16A, 17A, 18A, 19A, 20A, 21A, 22A, 23A, 24A, and 25A, respectively. FIGS. 10D, 11D, 12D, 13D, 14D, 15D, 16D, 17D, 18D, 19D, 20D, 21D, 22D, 23D, 24D, and 25D are cross-sectional views taken along line D-D′ of FIGS. 10A, 11A, 12A, 13A, 14A, 15A, 16A, 17A, 18A, 19A, 20A, 21A, 22A, 23A, 24A, and 25A, respectively.

Referring to FIGS. 10A, 10B, 10C, and 10D, a first photomask MP1 may be formed on the substrate 101.

The first photomask MP1 may include a single pattern formed by rectangles (or similar shapes) facing each other in the first horizontal direction (X direction) and a bridge BR connecting the rectangles and extending in the first oblique direction (L1 direction). The first photomask MP1 may be formed using an exposure process and/or a development process known in the art, and thus a detailed description thereof is omitted for the sake of brevity.

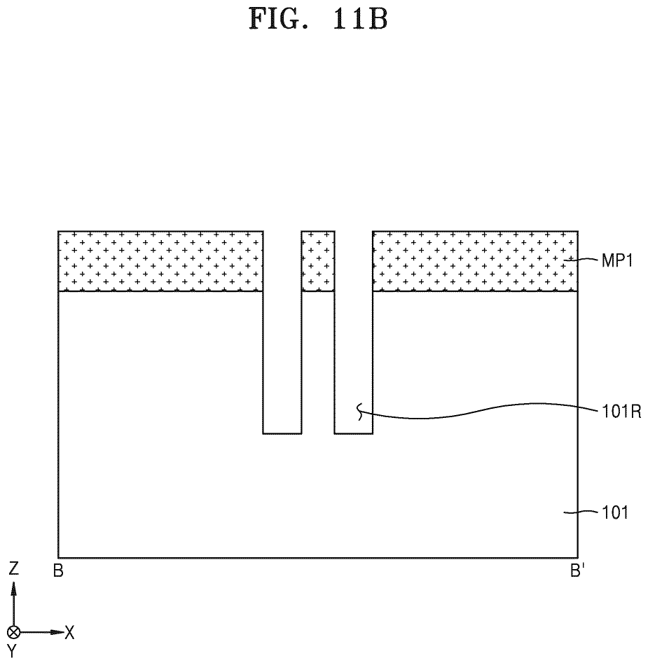

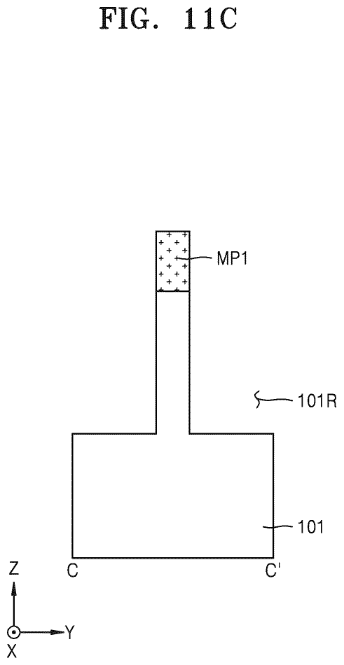

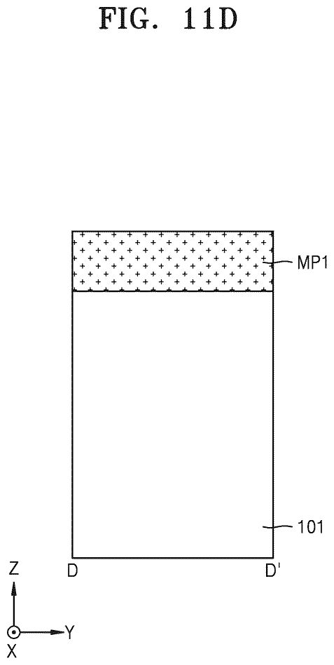

Referring to FIGS. 11A, 11B, 11C, and 11D, an etching process may be performed on the substrate 101 by using the first photomask MP1 as an etching mask.

By the etching process, a recess region 101R may be formed in the substrate 101. The recess region 101R may be formed within the substrate 101 to a predetermined depth. The etching process may be dry etching, for example. In some example embodiments, an inner wall of the recess region 101R may be tapered rather than vertical as illustrated in FIG. 11B. The etching process may be performed using techniques known in the art, and thus a detailed description thereof is omitted. After forming the recess region 101R, the first photomask MP1 may be removed by an ashing and stripping process.

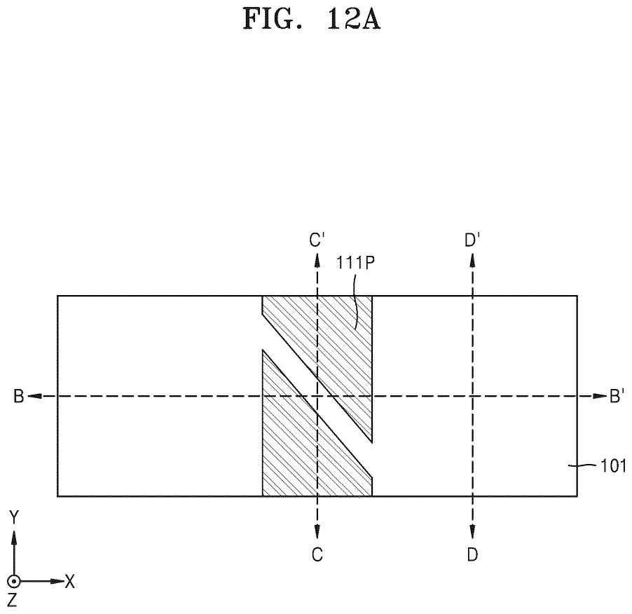

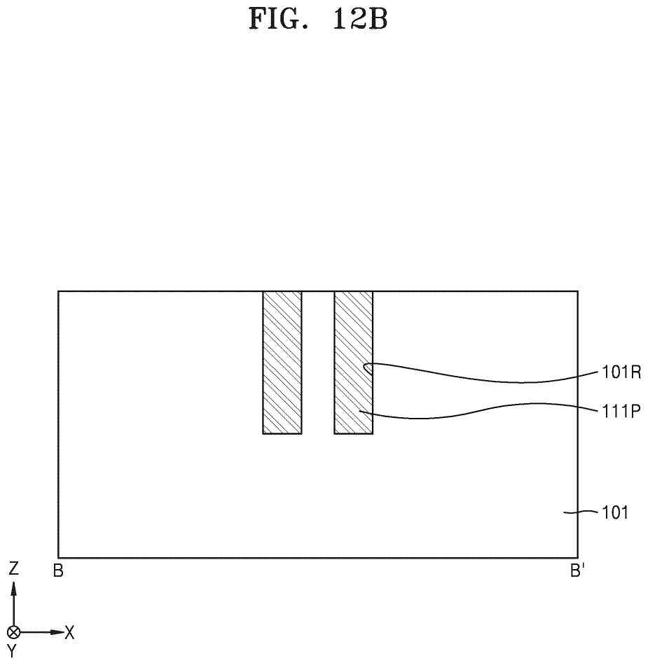

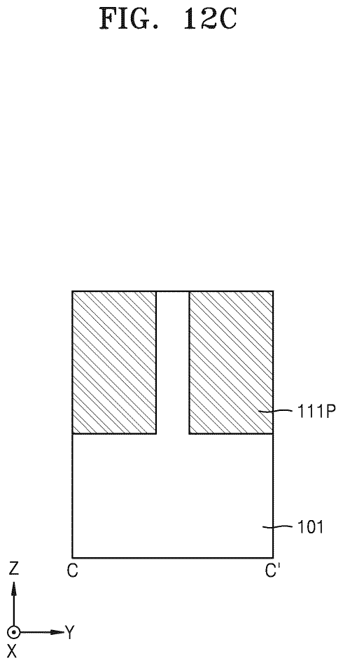

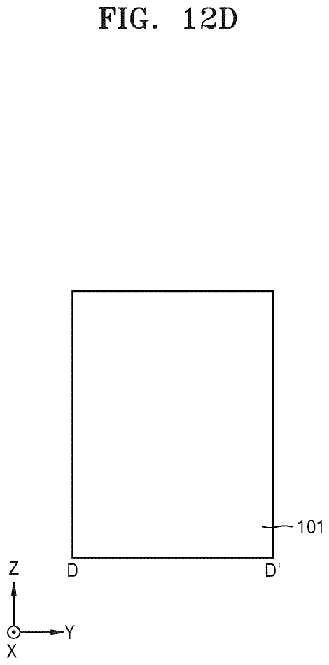

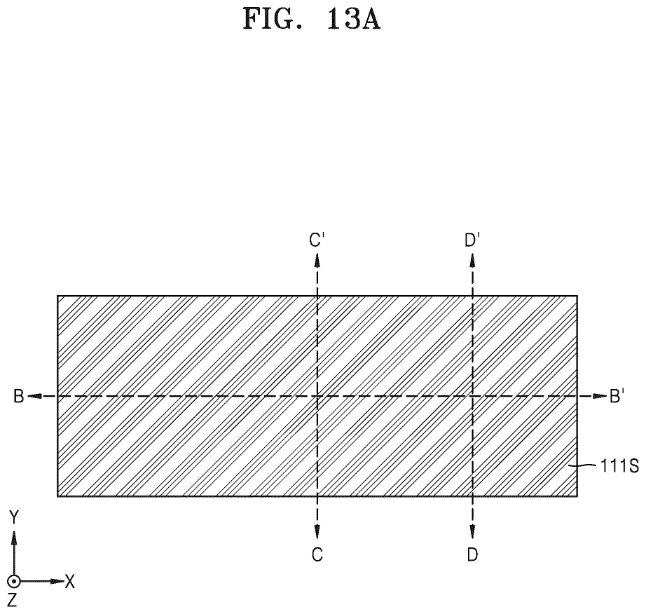

Referring to FIGS. 12A, 12B, 12C, and 12D, a preliminary lower insulating layer 111P may be formed to fill the recess region 101R.

The preliminary lower insulating layer 111P may include, for example, at least one of silicon oxide, silicon nitride, silicon oxynitride, or a low-k film. In some example embodiments, an upper surface of the substrate 101 may have the same vertical level as an upper surface of the preliminary lower insulating layer 111P. In other words, the upper surface of the substrate 101 may be flushed with the upper surface of the preliminary lower insulating layer 111P.

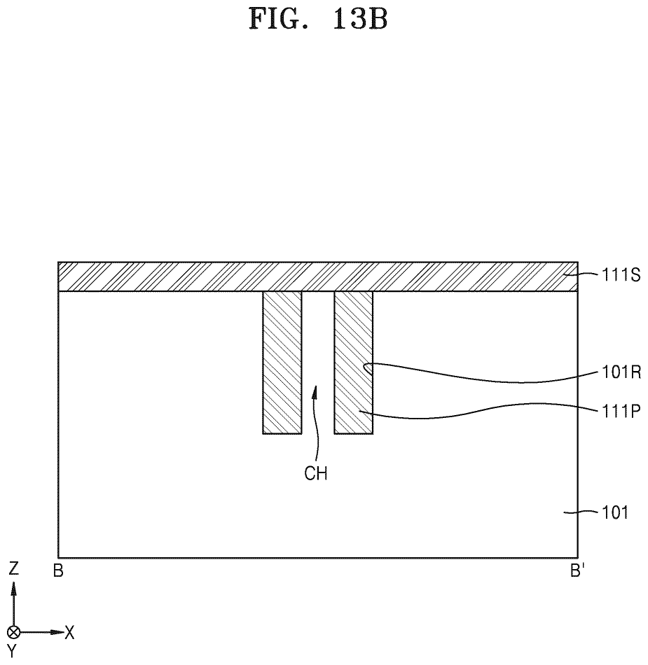

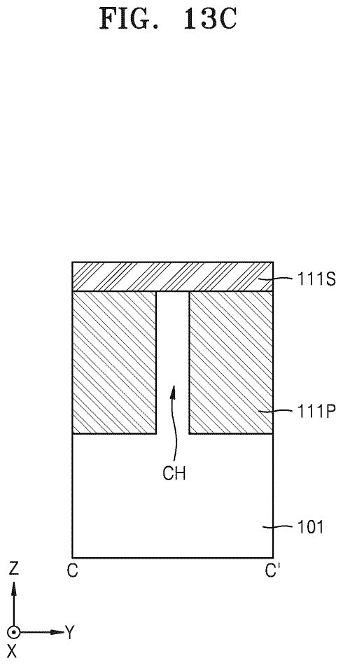

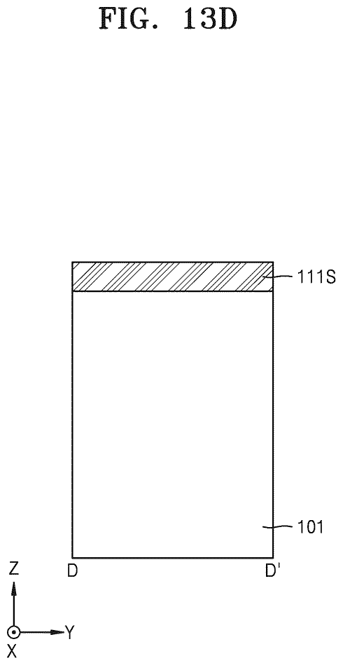

Referring to FIGS. 13A, 13B, 13C, and 13D, a sacrificial layer 111S may be formed to cover the upper surface of the substrate 101 and the upper surface of the preliminary lower insulating layer 111P.

After forming the sacrificial layer 111S, an impurity implantation process for well doping and channel doping may be performed on the substrate 101. Accordingly, the channel region CH may be formed in the central portion of the substrate 101. The impurity implantation process may be or include an ion implantation process. The impurity implantation process may be performed using techniques known in the art, a detailed description thereof is omitted. After the impurity implantation process, the sacrificial layer 111S may be removed.

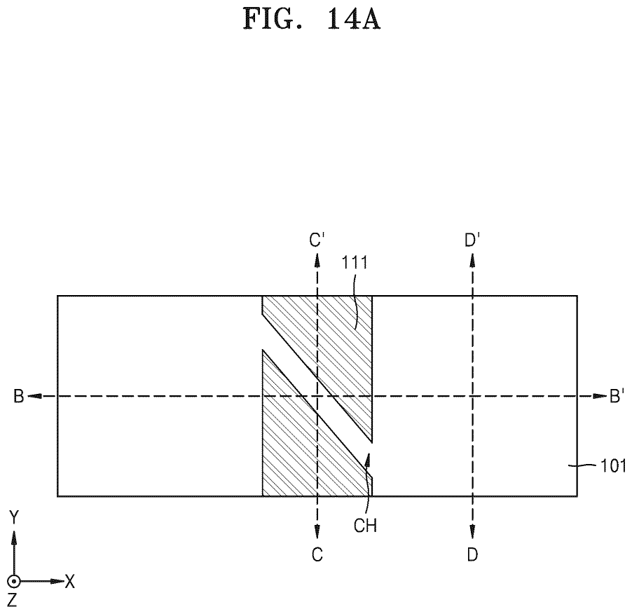

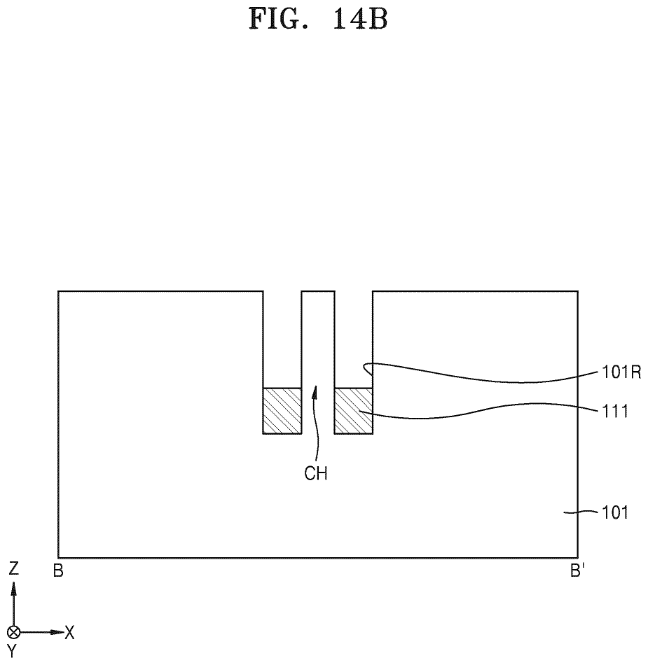

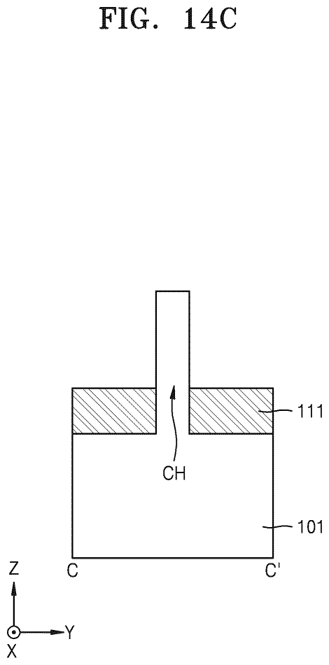

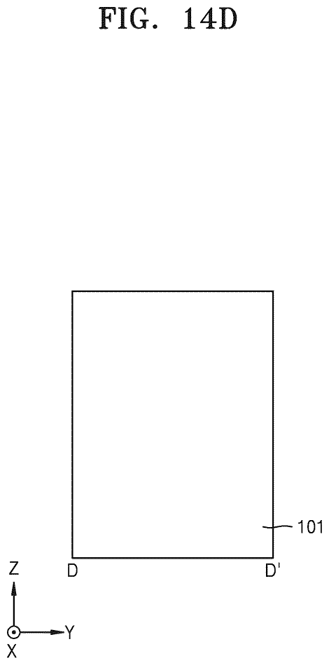

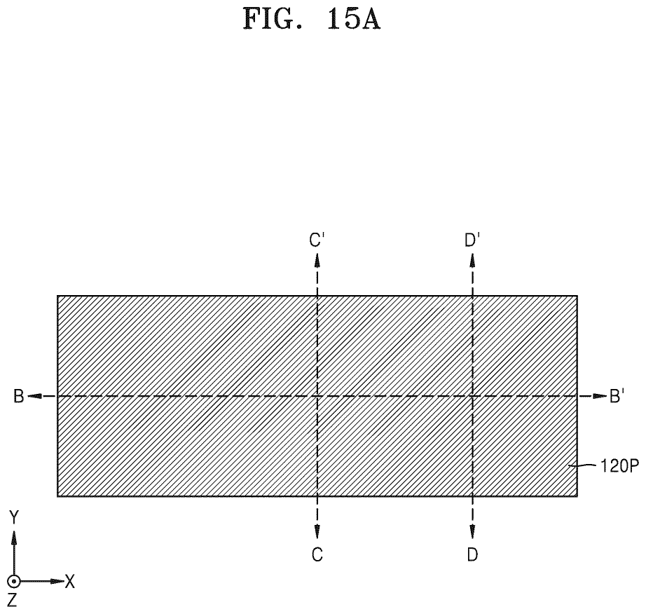

Referring to FIGS. 14A, 14B, 14C, and 14D, an upper portion of the preliminary lower insulating layer 111P may be etched to form the lower insulating layer 111 on the substrate 101.

By etching the upper portion, which is a portion of the preliminary lower insulating layer 111P, a portion of the recess region 101R may be exposed again. Accordingly, the upper surface of the lower insulating layer 111 may have a lower vertical level than the upper surface of the substrate 101. For example, the distances of the levels of the upper surface of the lower insulating layer 111 and the upper surface of the substrate 101 are both considered from/close to the base or lower surface of the substrate 101. As a result, a portion of the substrate 101 may have a shape that protrudes from the lower insulating layer 111 in the vertical direction (Z direction).

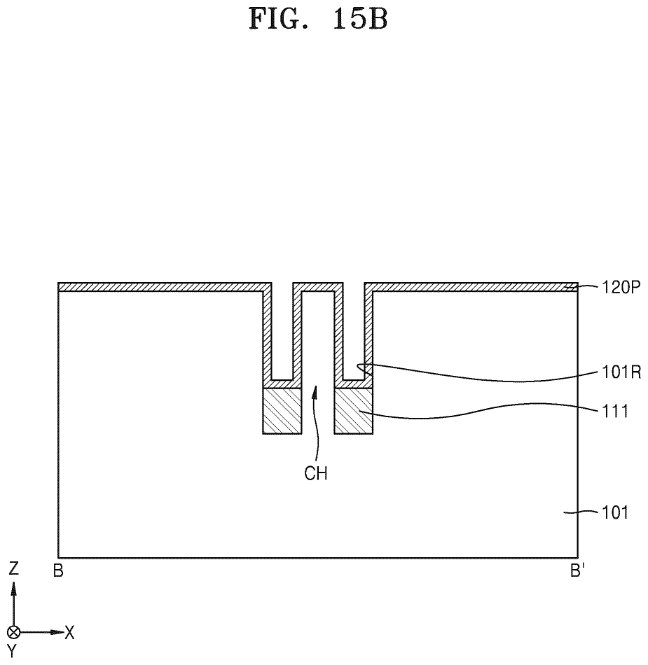

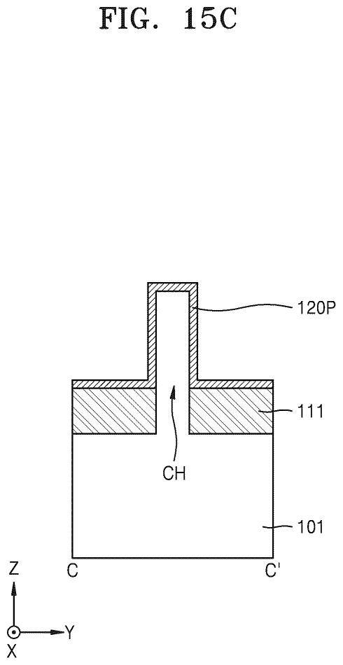

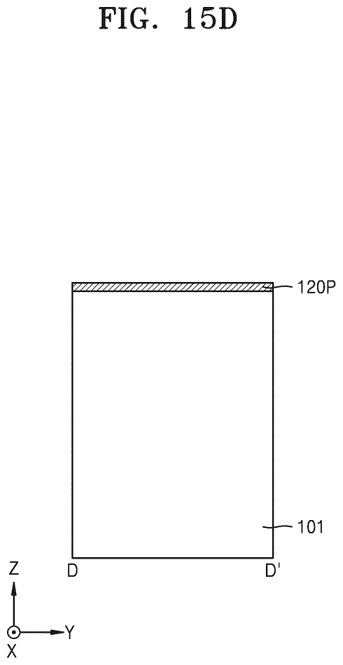

Referring to FIGS. 15A, 15B, 15C, and 15D, a preliminary gate dielectric film 120P may be formed to conformally cover the upper surface of the substrate 101, an inner wall of the recess region 101R, and the upper surface of the lower insulating layer 111.

In some example embodiments, the preliminary gate dielectric film 120P may include silicon oxide or silicon oxynitride. In some example embodiments, the preliminary gate dielectric film 120P may include at least one of high-k dielectric films. For example, the preliminary gate dielectric film 120P may include, but is not limited to, at least one of hafnium oxide, hafnium silicate, zirconium oxide, and zirconium silicate.

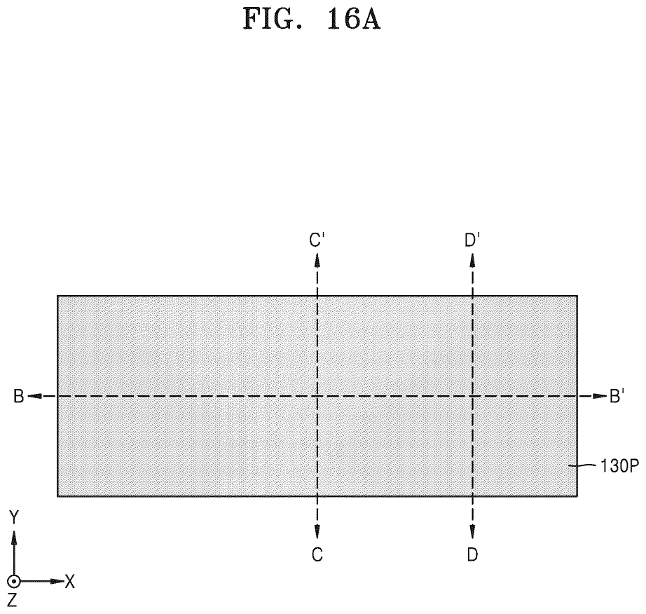

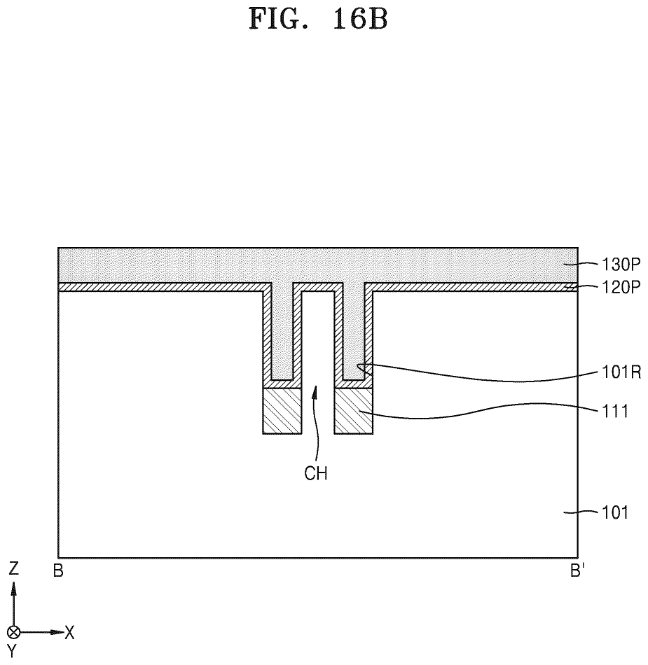

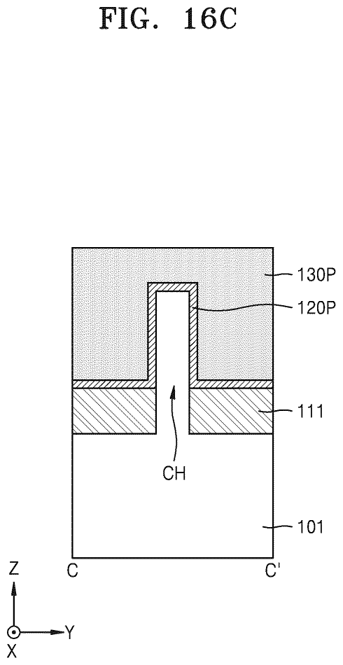

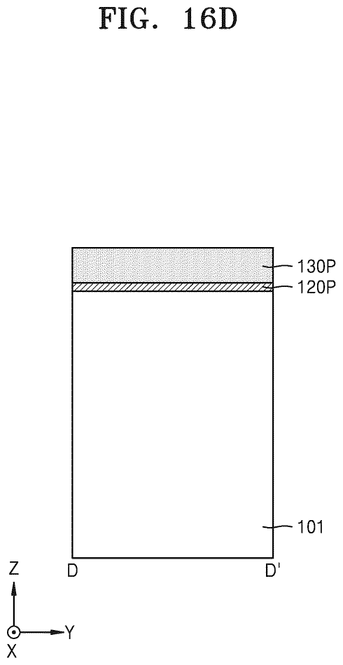

Referring to FIGS. 16A, 16B, 16C, and 16D, a preliminary gate electrode 130P may be formed to entirely fill the recess region 101R and cover an upper surface of the preliminary gate dielectric film 120P.

The preliminary gate electrode 130P may include a conductive material. The preliminary gate electrode 130P may include doped polysilicon, a metal, or a combination thereof. For example, the preliminary gate electrode 130P may include, but is not limited to, Al, Cu, Ti, Ta, W, Mo, TaN, NiSi, CoSi, TiN, WN, TiAl, TiAlN, TaCN, TaC, TaSiN, TiAlC, or a combination thereof. In some example embodiments, the upper surface of the preliminary gate electrode 130P may be formed as a flat or planar surface.

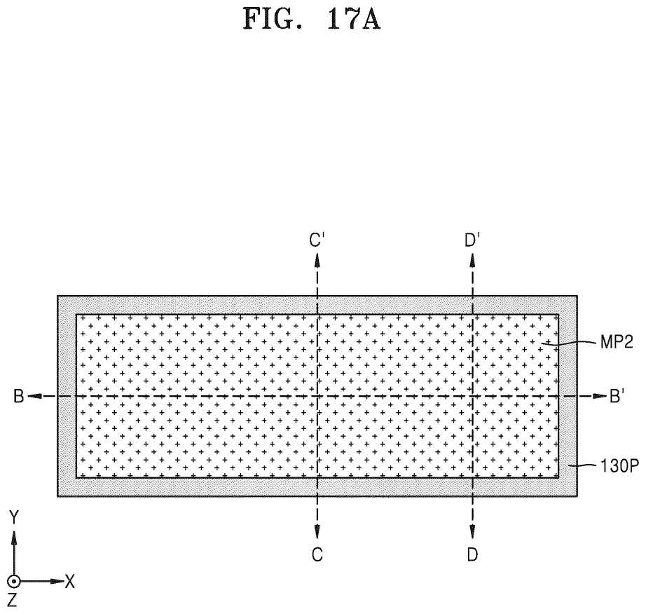

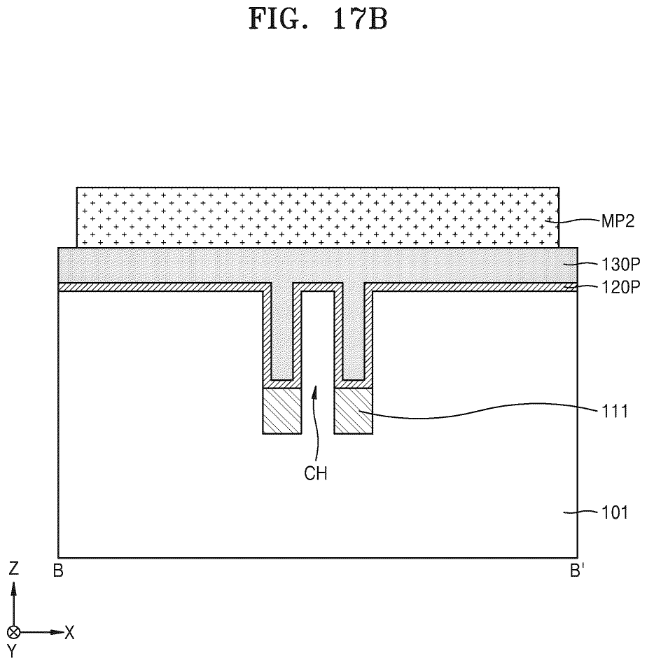

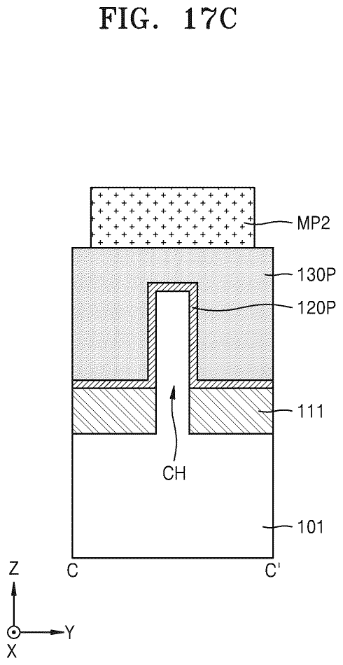

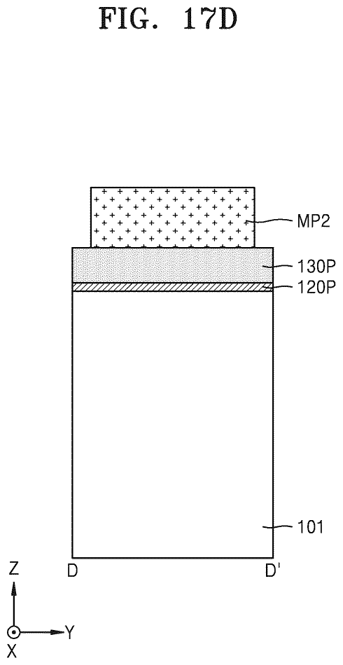

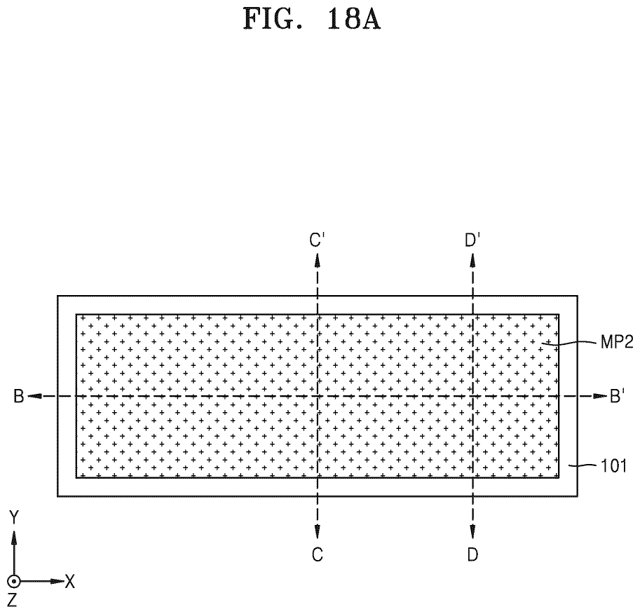

Referring to FIGS. 17A, 17B, 17C, and 17D, a second photomask MP2 may be formed on the preliminary gate electrode 130P.

The second photomask MP2 may be formed in a rectangular shape that is elongated in the first horizontal direction (X direction). The second photomask MP2 may define an active area. The second photomask MP2 may be formed using an exposure process and/or a development process known in the art, and thus a detailed description thereof is omitted for the sake of brevity.

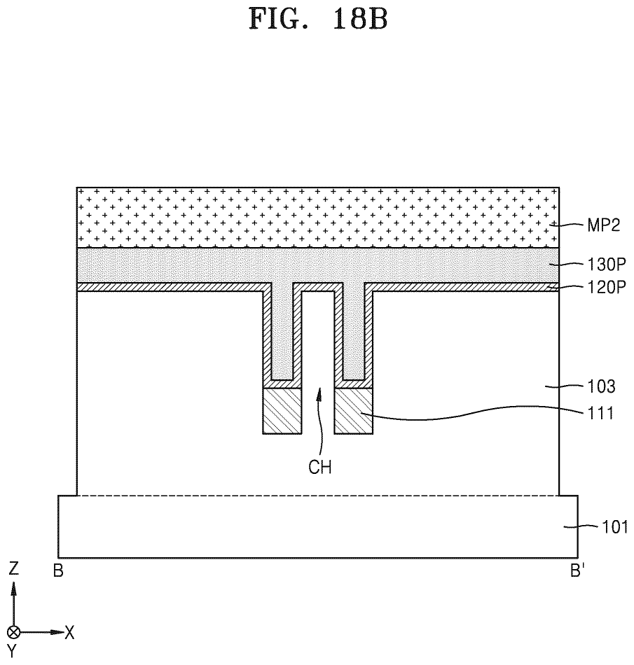

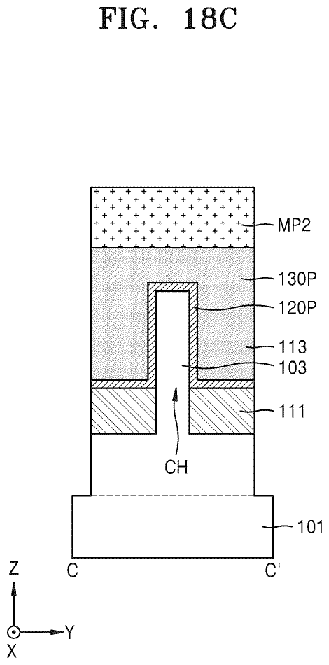

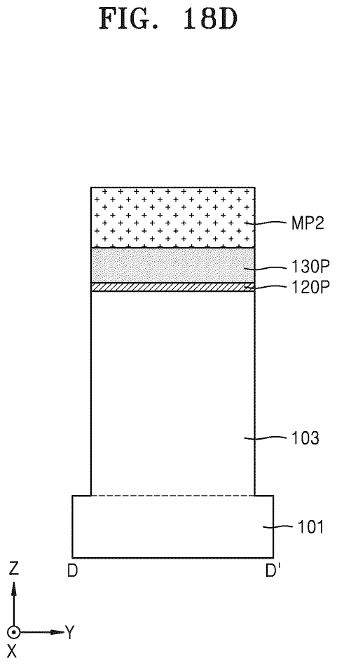

Referring to FIGS. 18A, 18B, 18C, and 18D, an etching process may be performed on the preliminary gate electrode 130P, the preliminary gate dielectric film 120P, and the substrate 101 by using the second photomask MP2 as an etching mask.

By the etching process, an outer portion of the preliminary gate electrode 130P and an outer portion of the preliminary gate dielectric film 120P may be removed. Additionally, lateral portions of the substrate 101 may be removed to form the fin-type body 103 on the substrate 101 by the etching process. The fin-type body 103 may define an active area of the semiconductor device 10. The etching process may be dry etching. In some example embodiments, a side wall of the fin-type body 103 may be tapered rather than vertical as illustrated in FIG. 18B. The etching process may be performed using techniques known in the art, and thus a detailed description thereof is omitted. After forming the fin-type body 103, the second photomask MP2 may be removed by an ashing and stripping process.

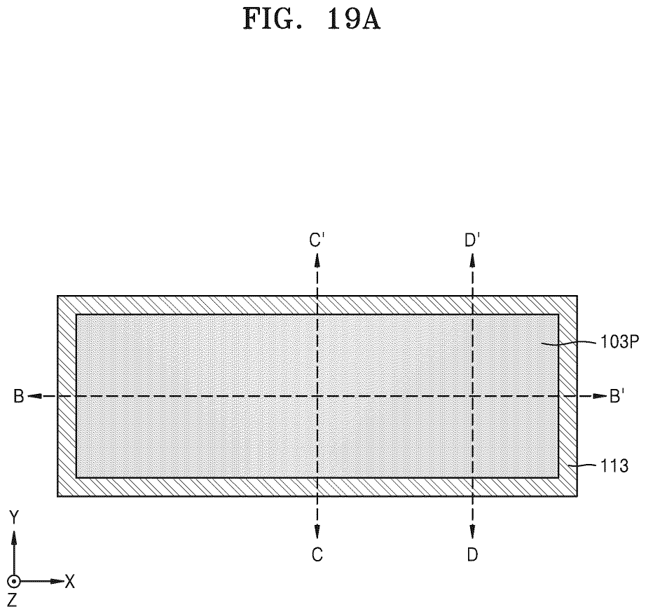

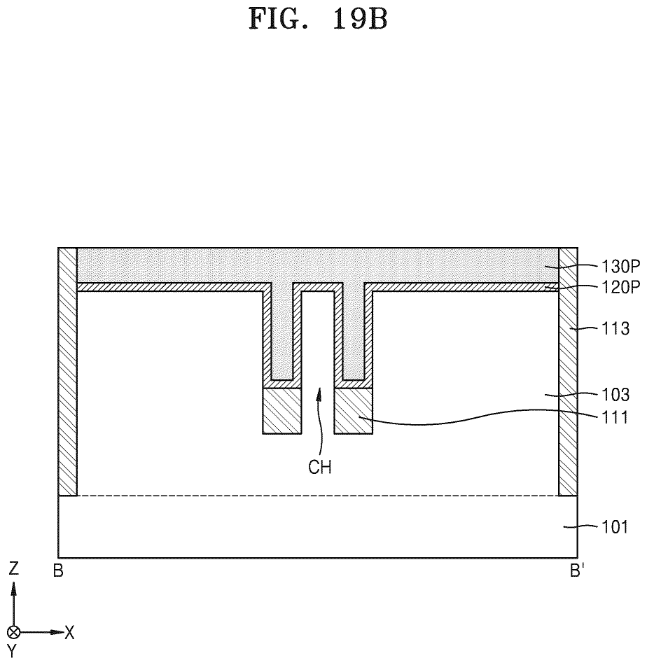

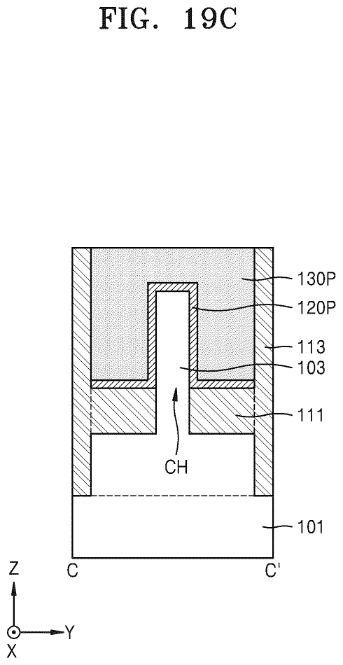

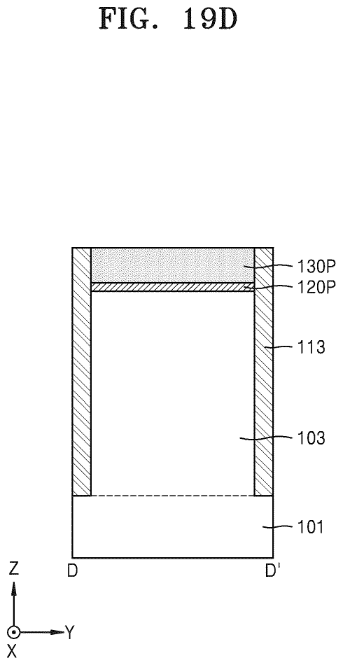

Referring to FIGS. 19A, 19B, 19C, and 19D, the sidewall insulating layer 113 may be formed to surround the side wall of the fin-type body 103.

The sidewall insulating layer 113 may include, for example, at least one of silicon oxide, silicon nitride, silicon oxynitride, or a low-k film. In some example embodiments, the upper surface of the preliminary gate electrode 130P may have the same vertical level as the upper surface of the sidewall insulating layer 113. In other words, the upper surface of the preliminary gate electrode 130P and the upper surface of the sidewall insulating layer 113 may be flushed.

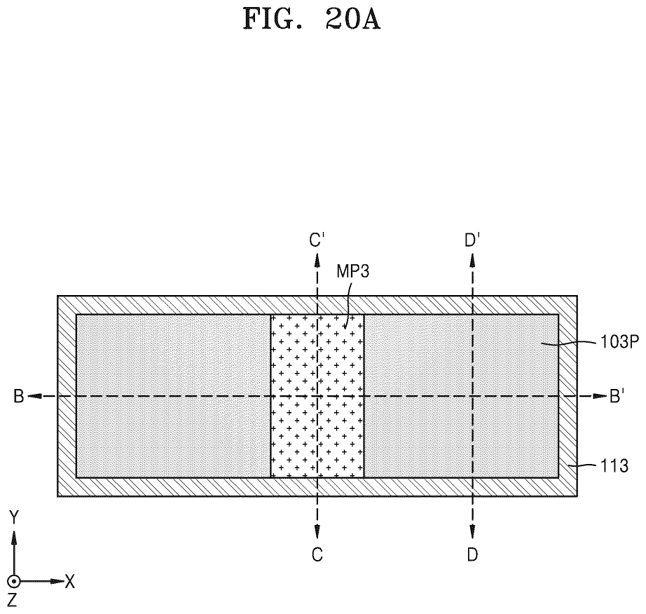

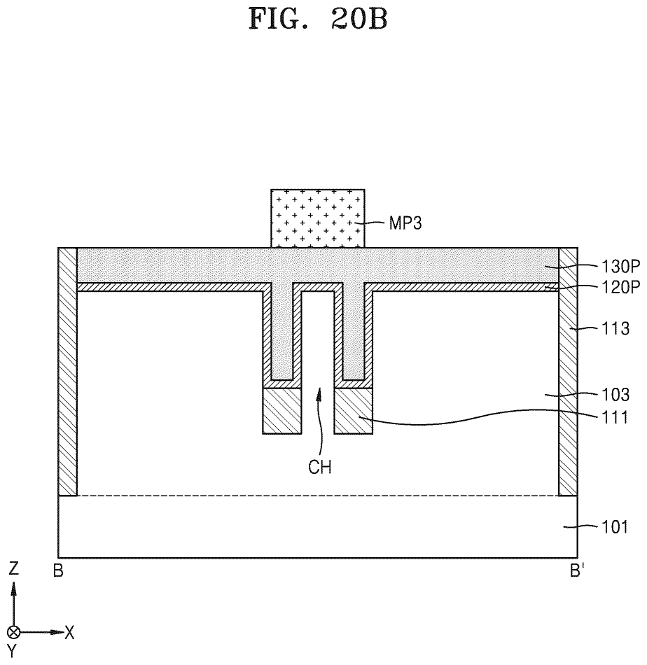

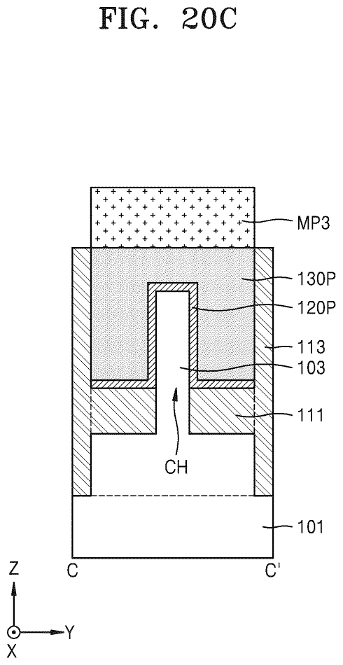

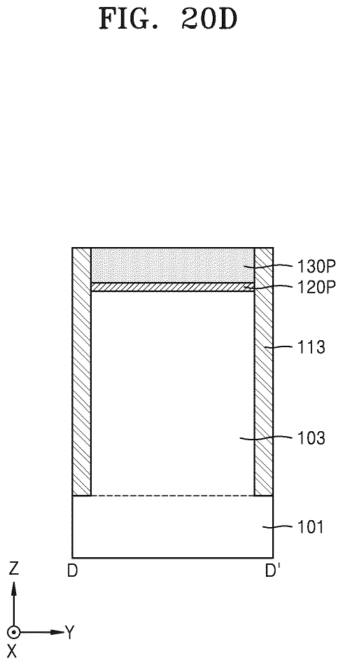

Referring to FIGS. 20A, 20B, 20C, and 20D, a third photomask MP3 may be formed on the preliminary gate electrode 130P.

The third photomask MP3 may be formed in a rectangular shape that is elongated in the second horizontal direction (Y direction). The third photomask MP3 may define a gate structure. The third photomask MP3 may be formed using an exposure process and/or a development process known in the art, and thus a detailed description thereof is omitted for the sake of brevity.

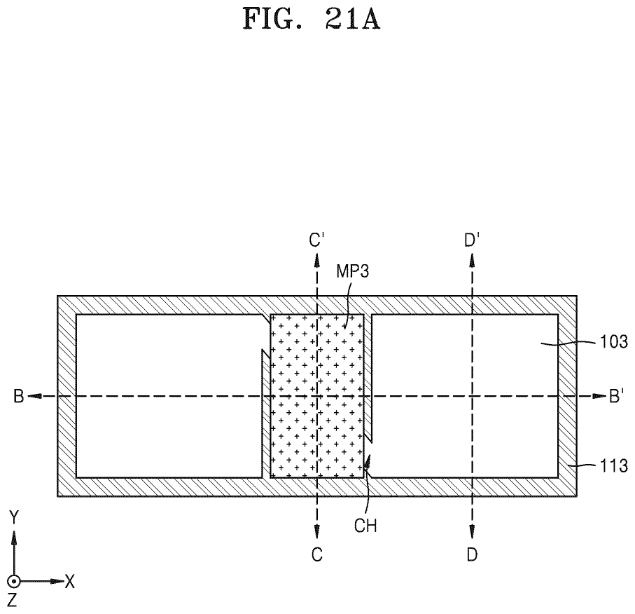

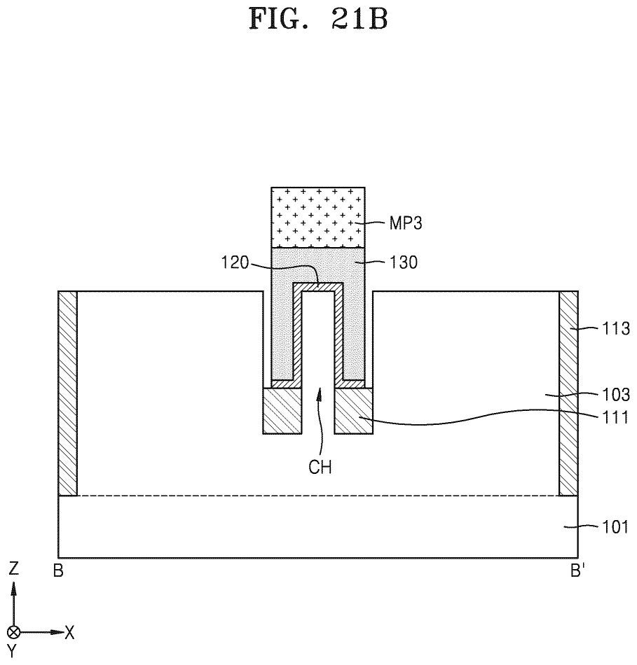

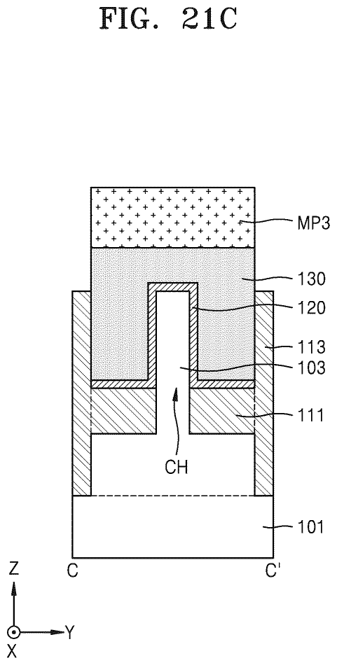

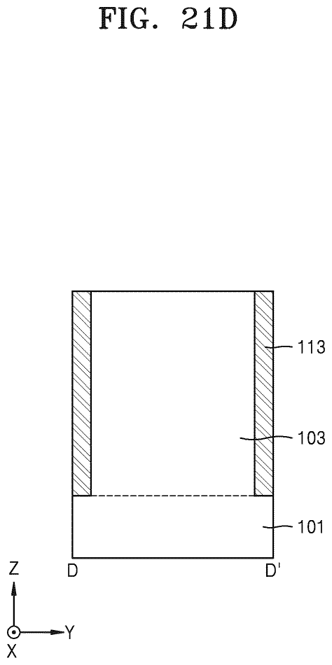

Referring to FIGS. 21A, 21B, 21C, and 21D, an etching process may be performed on the preliminary gate electrode 130P and the preliminary gate dielectric film 120P by using the third photomask MP3 as an etching mask.

By the etching process, the preliminary gate electrode 130P may be formed as the gate electrode 130, and the preliminary gate dielectric film 120P may be formed as the gate dielectric film 120. The etching process may be dry etching. In some example embodiments, a sidewall of the gate electrode 130 and a sidewall of the gate dielectric film 120 may each be tapered rather than vertical, as illustrated in FIG. 21B. As the etching process may be performed using techniques known in the art, and therefore a detailed description thereof is omitted.

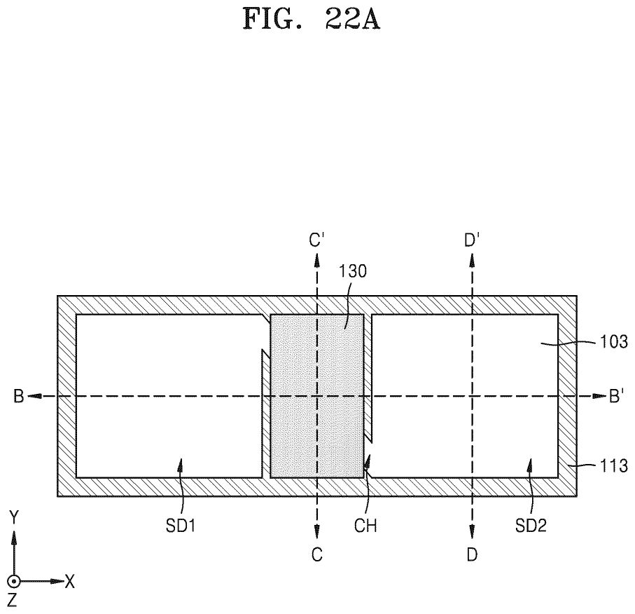

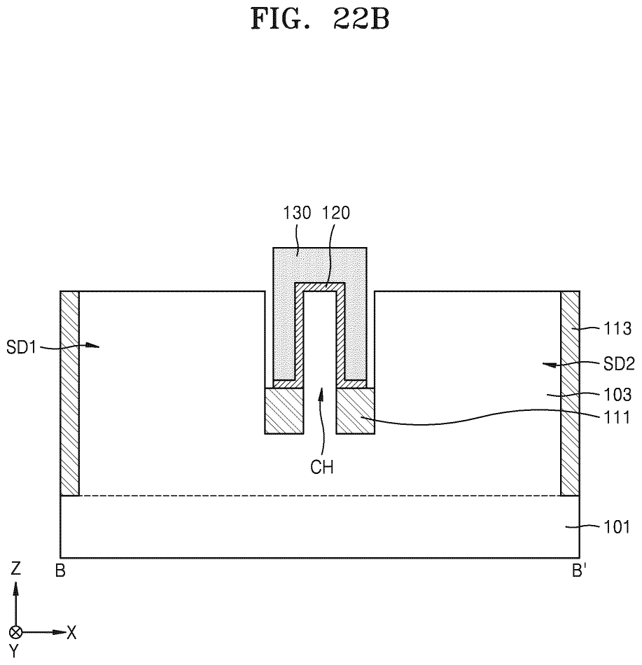

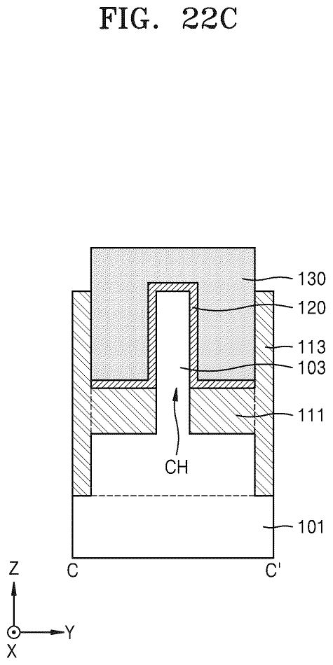

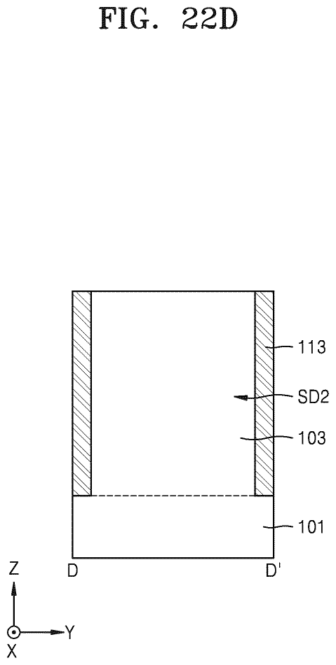

Referring to FIGS. 22A, 22B, 22C, and 22D, an impurity implantation process for source/drain doping may be performed on the substrate 101.

The impurity implantation process may be or include an ion implantation process. By implanting a relatively higher concentration of dopant, for example, an n-type dopant, into the fin-type body 103, the first source/drain region SD1 and the second source/drain region SD2 may be formed. Accordingly, the first source/drain region SD1, the channel region CH, and the second source/drain region SD2 may be formed in the first horizontal direction (X direction) within the fin-type body 103. The first source/drain region SD1 and the second source/drain region SD2 may be formed on opposite sides of the fin-type body 103, respectively. After forming the first and second source/drain regions SD1 and SD2, the third photomask MP3 may be removed by an ashing and stripping process.

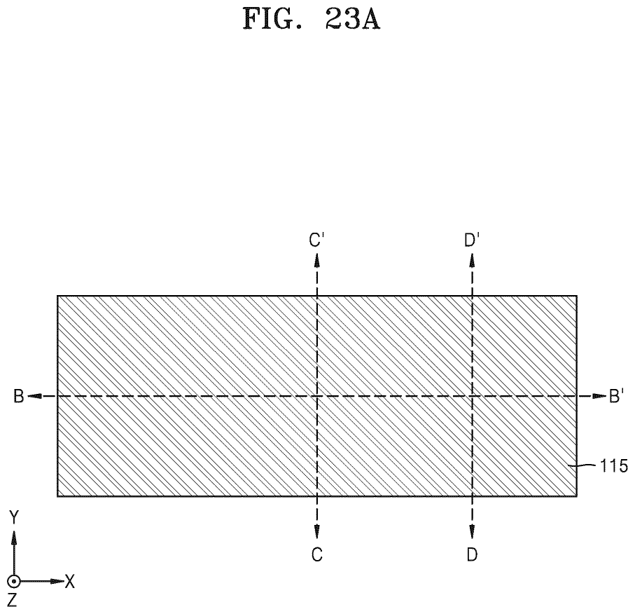

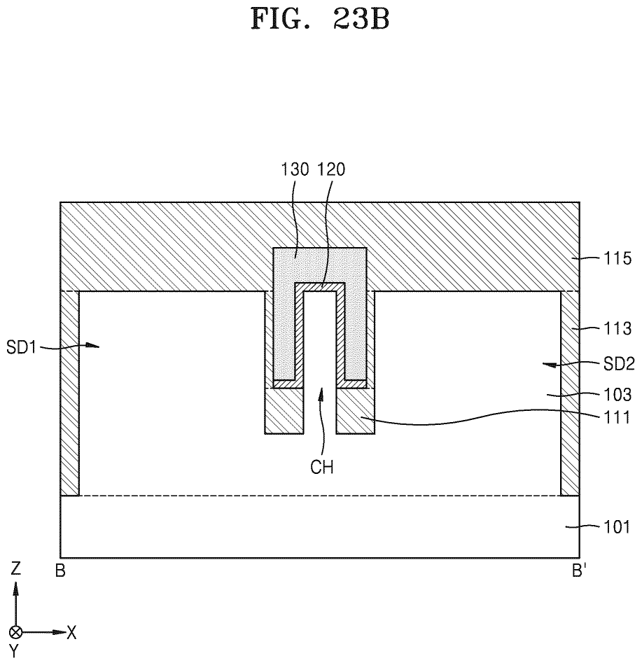

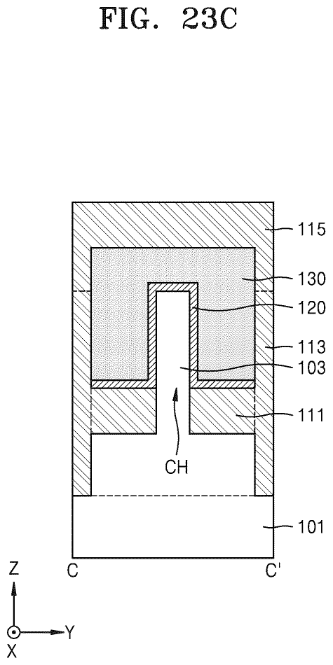

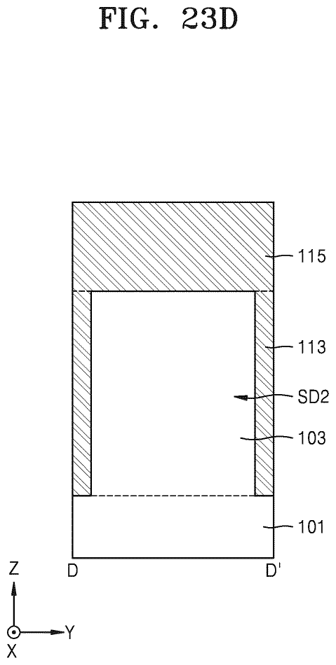

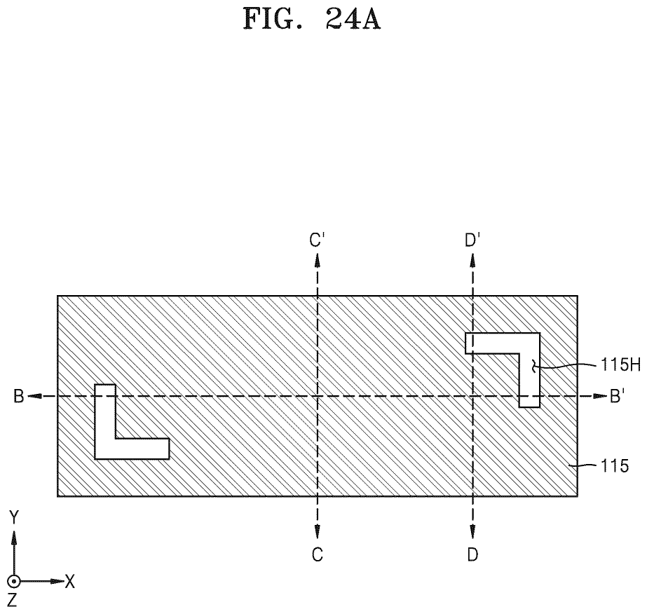

Referring to FIGS. 23A, 23B, 23C, and 23D, the upper insulating layer 115 may be formed to cover all of the fin-type body 103, the sidewall insulating layer 113, the gate dielectric film 120, and the gate electrode 130.

The upper insulating layer 115 may include, for example, at least one of silicon oxide, silicon nitride, silicon oxynitride, or a low-k film. In some example embodiments, an upper surface of the upper insulating layer 115 may be formed as a flat or planar surface.

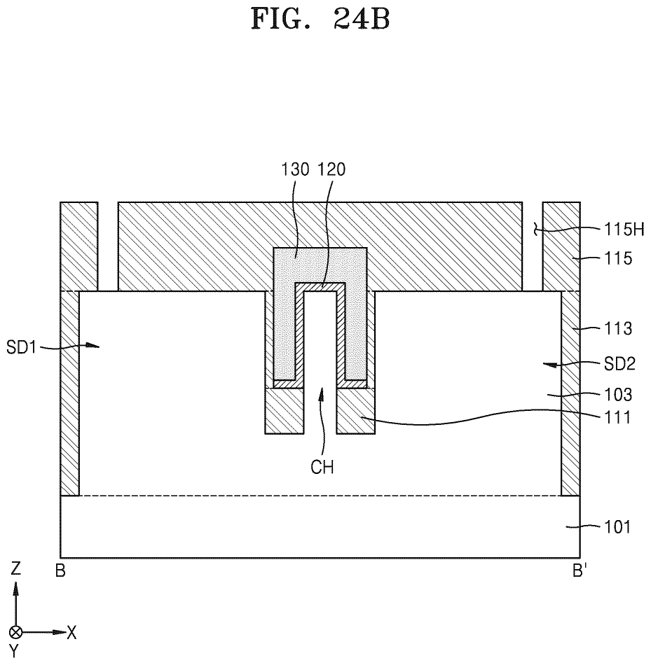

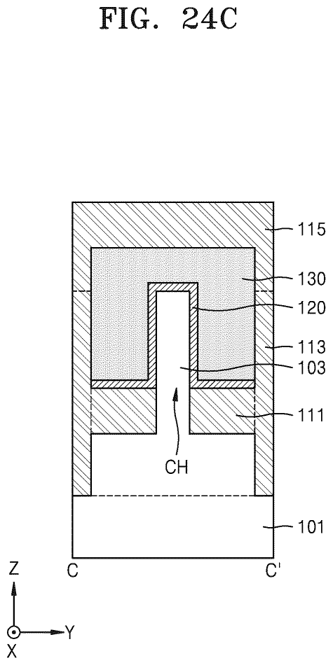

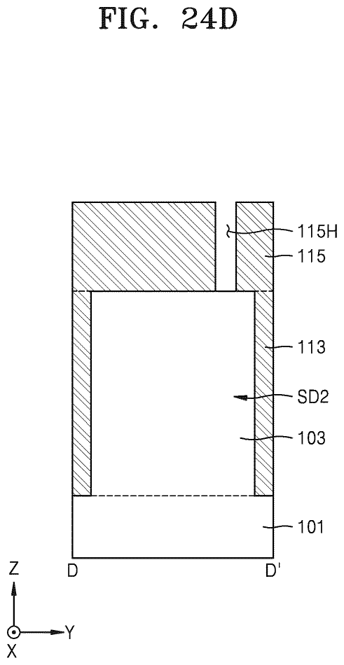

Referring to FIGS. 24A, 24B, 24C, and 24D, a fourth photomask may be formed, and a pair of contact holes 115H may be formed in the upper insulating layer 115 by using the fourth photomask as an etching mask.

By the etching process, a portion of each of the first and second source/drain regions SD1 and SD2 may be exposed to the outside by the pair of contact holes 115H. The pair of contact holes 115H may define an area defining a source contact and a drain contact. The etching process may be performed using techniques known in the art, and thus a detailed description thereof is omitted.

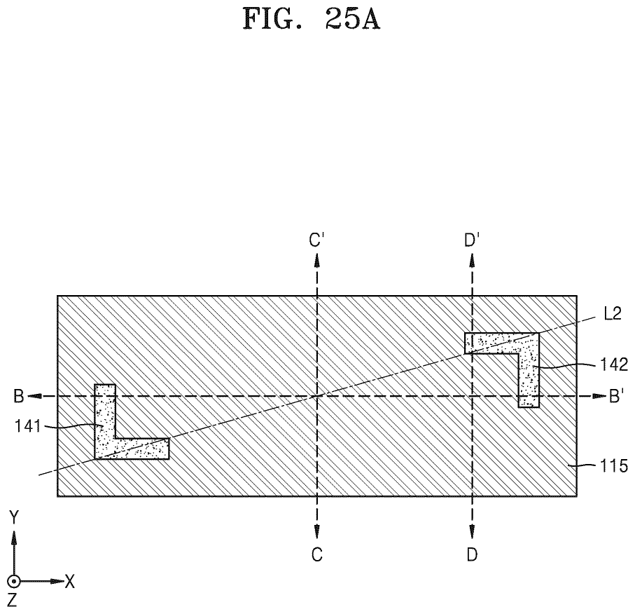

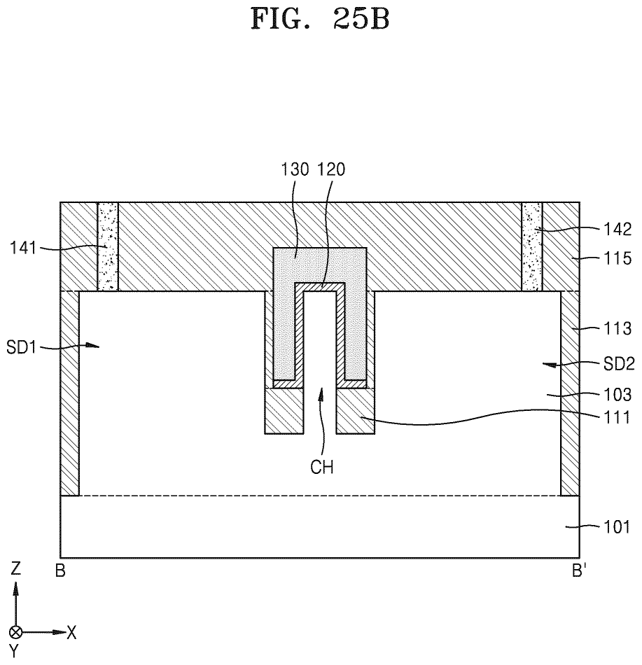

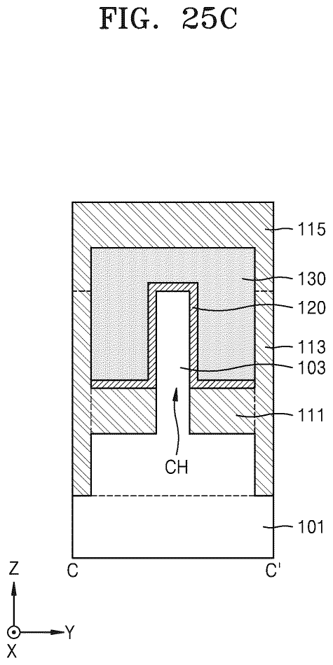

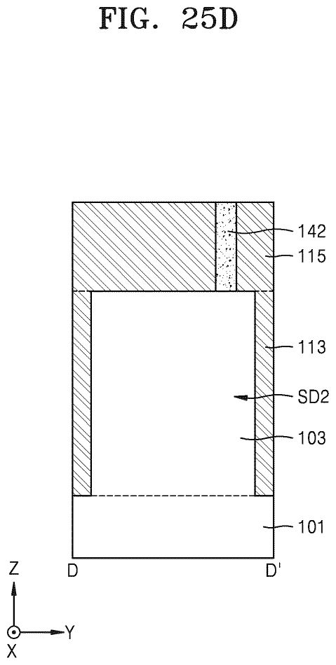

Referring to FIGS. 25A, 25B, 25C, and 25D, the first and second contacts 141 and 142 may be formed to fill both of the pair of contact holes 115H.

The first contact 141 may be formed on the first source/drain region SD1, and the second contact 142 may be formed on the second source/drain region SD2. The first and second contacts 141 and 142 may include a conductive material. The first and second contacts 141 and 142 may include, but are not limited to, Al, Cu, Ti, Ta, W, Mo, TaN, NiSi, CoSi, TiN, WN, TiAl, TiAlN, TaCN, TaC, TaSiN, TiAlC, or a combination thereof, for example. The first contact 141 may be referred to as a source contact, and the second contact 142 may be referred to as a drain contact. The first and second contacts 141 and 142 may be spaced from each other in the second oblique direction (L2 direction), which is an imaginary straight line connecting the furthest ends of the first and second contacts 141 and 142.

Through this manufacturing method, the semiconductor device 10 according to some example embodiments of the inventive concepts may be manufactured. Although not described, a person skilled in the art will be able to infer the method of manufacturing semiconductor devices 20 and 30 through the method of manufacturing the semiconductor device 10 described above.

According to some example embodiments of the inventive concepts, a method of manufacturing a semiconductor device includes forming a fin-type body protruding in a vertical direction on a substrate and extending in a first horizontal direction, forming a channel region in a center portion of the fin-type body by performing a first impurity implantation process on the fin-type body, forming a dielectric film that conformally covers the substrate and the fin-type body, forming an electrode film covering the dielectric film; forming a gate dielectric film and a gate electrode by patterning the dielectric film and the electrode film; forming a first source/drain region on a first side of the fin-type body, and a second source/drain region on a second side of the fin-type body by performing a second impurity implantation process on the fin-type body, and forming a first contact on the first source/drain region and a second contact on the second source/drain region. The channel region extends in a first oblique direction, and an imaginary straight line connecting furthest ends of the first and second contacts extends in a second oblique direction transverse to the first oblique direction.

In some example embodiments, the forming of the fin-type body may include forming a photomask on the substrate, and etching the substrate by using the photomask as an etching mask. The photomask includes a single pattern formed by rectangles facing each other in the first horizontal direction and a bridge connecting the rectangles and extending in the first oblique direction.

In some example embodiments, in the etching of the substrate, the substrate and the fin-type body may include a same material and a same crystal structure as each other.

In some example embodiments, in the etching of the substrate, the first and second source/drain regions and the channel region may have a same height in the vertical direction.

In some example embodiments, a region of the substrate, corresponding to the bridge, may be formed as the channel region, and the fin-type body may be formed in a zee (Z) shape.

In some example embodiments, the gate dielectric film may be formed to extend in the first oblique direction, and the gate electrode may be formed to extend in a second horizontal direction that perpendicularly intersects with the first horizontal direction.

In some example embodiments, in the first horizontal direction, a length of the first source/drain region may be substantially equal to a length of the second source/drain region, and a length of the channel region may be less than each of the lengths of the first and second source/drain regions., and in the second horizontal direction, the length of the first source/drain region, the length of the second source/drain region, and the length of the channel region may be substantially equal to each other.

In some example embodiments, the first and second contacts may be point-symmetrical with respect to a center point on an imaginary straight line in the first oblique direction.

In some example embodiments, the first and second contacts may be each formed in an L-shape.

In some example embodiments, the first and second contacts may be each formed in a triangular shape.

Example embodiments are not necessarily mutually exclusive. For example, some example embodiments may include one or more features described with reference to one or more figures, and may also include one or more other features described with reference to one or more other figures.

While several example embodiments have been provided in the present disclosure, it should be understood that the disclosed systems and methods might be embodied in many other forms without departing from the spirit or scope of the present disclosure. The present example embodiments are to be considered as illustrative and not restrictive, and the intention is not to be limited to the details given herein. For example, the various elements or components may be combined or integrated in another system or certain features may be omitted, or not implemented.

What is claimed is:

1. A semiconductor device comprising:
a substrate;
a fin-type body protruding vertically on the substrate and extending in a first horizontal direction;
a first source/drain region on a first side of the fin-type body and a second source/drain region on a second side of the fin-type body;
a channel region between the first source/drain region and the second source/drain region in the fin-type body;
a gate electrode surrounding the channel region and extending in a second horizontal direction that is perpendicular to and intersects the first horizontal direction;
a gate dielectric film between the channel region and the gate electrode; and
a first contact on the first source/drain region and a second contact on the second source/drain region,
wherein the channel region extends in a first oblique direction, and
an imaginary straight line connecting furthest ends of the first contact and the second contact extends in a second oblique direction transverse to the first oblique direction.

2. The semiconductor device of claim 1, wherein, in a plan view, the first source/drain region and the second source/drain region are each in a rectangular shape, and the channel region has a parallelogram shape.

3. The semiconductor device of claim 2, wherein a first end of the channel region is in contact with a first edge of the first source/drain region, and
a second end of the channel region is in contact with a second edge of the second source/drain region.

4. The semiconductor device of claim 3, wherein the fin-type body has a zee (Z) shape.

5. The semiconductor device of claim 3, wherein the first contact is adjacent a third edge of the first source/drain region, the third edge being furthest from the first edge, and
the second contact is adjacent a fourth edge of the second source/drain region, the fourth edge being furthest from the second edge.

6. The semiconductor device of claim 5, wherein the first contact and the second contact are point-symmetrical with respect to a center point located on an imaginary straight line in the first oblique direction.

7. The semiconductor device of claim 6, wherein the first contact and the second contact each include a portion extending in the first horizontal direction and a portion extending in the second horizontal direction.

8. The semiconductor device of claim 6, wherein the first contact and the second contact each have a triangular shape.

9. The semiconductor device of claim 1, wherein, in the first horizontal direction, a length of the first source/drain region is equal to a length of the second source/drain region, and a length of the channel region is less than each of the lengths of the first source/drain region and the second source/drain region.

10. The semiconductor device of claim 9, wherein, in the second horizontal direction, the length of the first source/drain region, the length of the second source/drain region, and the length of the channel region are equal to each other.

11. A semiconductor device comprising:
a transistor on a substrate, the transistor comprising,
a fin-type body extending in a first horizontal direction;
a first source/drain region defining a first side of the fin-type body and a second source/drain region defining a second side of the fin-type body;
a channel region defining a portion between the first source/drain region and the second source/drain region of the fin-type body;
a gate electrode surrounding the channel region and extending in a second horizontal direction that is perpendicular to and intersects the first horizontal direction;
a gate dielectric film between the channel region and the gate electrode; and
a first contact on the first source/drain region and a second contact on the second source/drain region,
wherein the channel region extends in a zigzag manner in the first horizontal direction and the second horizontal direction,
a first imaginary straight line connecting furthest ends of the channel region extends in a first oblique direction, and
a second imaginary straight line connecting furthest ends of the first contact and the second contact extends in a second oblique direction transverse to the first oblique direction.

12. The semiconductor device of claim 11, wherein the transistor comprises a high-voltage transistor having an operating voltage of 20 V or higher.

13. The semiconductor device of claim 11, wherein the first source/drain region and the second source/drain region and the channel region comprise a same material and a same crystal structure.

14. The semiconductor device of claim 11, wherein, in the channel region, a number of portions of the channel region that extend in the first horizontal direction is one more than a number of portions of the channel region that extend in the second horizontal direction.

15. The semiconductor device of claim 11, wherein the first contact and the second contact each have an L shape or a triangular shape.

16. A semiconductor device comprising:
a high-voltage transistor, the high-voltage transistor comprising,
a substrate;
a fin-type body, the fin-type body defining a portion of the substrate, and protruding in a vertical direction on an upper surface of the substrate and extending in a first horizontal direction;
a gate electrode surrounding a central portion of the fin-type body on the substrate and extending in a second horizontal direction that is perpendicular to and intersects the first horizontal direction;
a gate dielectric film between the fin-type body and the gate electrode;
a source region having a rectangular shape and defining a first side of the fin-type body and a drain region having a rectangular shape and defining a second side of the fin-type body;
a channel region defining a central portion of the fin-type body and extending in a first diagonal direction between a sidewall of the source region and a sidewall of the drain region, the sidewall of the source region and the sidewall of the drain region facing each other; and
a source contact on the source region and a drain contact on the drain region,
wherein a first imaginary straight line connecting furthest ends of the source contact and the drain contact extends in a second diagonal direction transverse to the first diagonal direction.

17. The semiconductor device of claim 16, wherein, in a plan view, the channel region is point-symmetrical with respect to a center point located on the first imaginary straight line in the second diagonal direction, and
the source contact and the drain contact are point-symmetrical with respect to the center point, the center point being on a second imaginary straight line in the first diagonal direction.

18. The semiconductor device of claim 17, wherein the source contact and the drain contact are at a furthest distance from the channel region.

19. The semiconductor device of claim 16, wherein the gate dielectric film conformally covers an upper surface and both side walls of the channel region and extends in the first diagonal direction.

20. The semiconductor device of claim 16, wherein the source region, the drain region, and the channel region have a same height in the vertical direction and have a same material and a same crystal structure.
